(19) United States
(12) Patent Application Publication
(10) Pub. No.: US 2022/0246890 A1
(43) Pub. Date: Aug. 4, 2022

(54) DISPLAY DEVICE AND ELECTRONIC APPARATUS

(71) Applicant: Sony Group Corporation, Tokyo (JP)

(72) Inventor: Keiji Sugi, Kanagawa (JP)

(21) Appl. No.: 17/603,711

(22) PCT Filed: Apr. 6, 2020
(86) PCT No.: PCT/JP2020/015549

§ 371 Date: Oct. 14, 2021

(30) Foreign Application Priority Data
Apr. 26, 2019 (JP) 2019-086857

(51) Int. Cl. H01L 51/52; H01L 33/58

(52) U.S. Cl. CPC H01L 51/5275; H01L 25/167; H01L 33/58

(57) ABSTRACT

A display device includes a substrate having a principal surface; plural light-emitting elements provided on the principal surface; and plural structures that are provided on the plural light-emitting elements and that have side surfaces vertical or substantially vertical to the principal surface. The refractive index between the structures is lower than a refractive index of the structures, and a pitch of the light-emitting elements is three times or less a pitch of the structures.

### TECHNICAL FIELD

The present disclosure relates to a display device and an electronic apparatus.

### BACKGROUND ART

In order to realize high luminance and low power consumption in micro displays such as Micro-OLEDs (Micro-Organic Light Emitting Diodes) and Micro-LEDs (Micro-Light Emitting Diodes), it is required to enhance efficiency by improving the utilization efficiency of emitted light.

For example, PTL 1 describes that a hemispherical lens is formed on a light-emitting element to condense light in the vicinity of the front, thereby enhancing the utilization efficiency of light.

### CITATION LIST

### Patent Literature

### [PTL 1]

Japanese Patent Laid-Open No. 2013-114772

### SUMMARY

### Technical Problem

In a case of a surface light source such as a micro display, it is necessary to enhance the utilization efficiency of light as a whole light source, and it is effective to improve the condensation of light in the vicinity of the outer periphery of the light source when considering the area ratio. However, although the effect of condensing light in the vicinity of the focal point, that is, in the vicinity of the center of the light-emitting element, to the front is significant in the hemispherical lens, the effect of condensing light in the vicinity of the outer periphery of the light-emitting element is disadvantageously small.

An object of the present disclosure is to provide a display device and an electronic apparatus including the same that are capable of enhancing a light condensing effect in the vicinity of the outer periphery of a light-emitting element.

### Solution to Problem

In order to solve the above-described problem, according to a first disclosure, a display device includes a substrate having a principal surface, plural light-emitting elements provided on the principal surface, and plural structures that are provided on the plural light-emitting elements and that have side surfaces vertical or substantially vertical to the principal surface, a refractive index between the structures is lower than a refractive index of the structures, and a pitch of the light-emitting elements is three times or less a pitch of the structures.

According to a second disclosure, a display device includes a substrate having a principal surface, plural light-emitting elements provided on the principal surface, and plural structures that are provided on the plural light-emitting elements and that have side surfaces vertical or substantially vertical to the principal surface, a refractive index of a portion between the structures is lower than the refractive index of the structures, and the pitch of the light-emitting elements is n times or more (n is an integer equal to or larger than 1) the pitch of the structures.

According to a third disclosure, an electronic apparatus includes the display device according to the first or second disclosure.

### BRIEF DESCRIPTION OF DRAWINGS

FIG. 1 is a schematic diagram for illustrating an example of an entire configuration of a display device according to an embodiment of the present disclosure.

FIG. 2A is a cross-sectional view for illustrating an example of a configuration of the display device according to the embodiment of the present disclosure. FIG. 2B is a cross-sectional view along the line IIB-IIB of FIG. 2A.

FIG. 3 is an enlarged cross-sectional view for illustrating an example of a configuration of an organic layer illustrated in FIG. 2A.

FIG. 4A and FIG. 4B are cross-sectional views each explaining an example of a step of forming a microlens array.

FIG. 5 is a cross-sectional view for illustrating a modified example of microlenses.

FIG. 6 is a cross-sectional view for illustrating a modified example of the microlenses.

FIG. 7 is a cross-sectional view for illustrating a modified example of the microlenses.

FIG. 8 is a cross-sectional view for illustrating a modified example of the microlenses.

FIG. 9 is a cross-sectional view for illustrating a modified example of the microlenses.

FIG. 10 is a cross-sectional view for illustrating a modified example of the microlenses.

FIG. 11 is a cross-sectional view for illustrating a modified example of the microlenses.

FIG. 12 is a cross-sectional view for illustrating a modified example of the microlenses.

FIG. 13 is a cross-sectional view for illustrating a modified example of the microlenses.

FIG. 14 is a cross-sectional view for illustrating a modified example of the microlenses.

FIG. 15 is a cross-sectional view for illustrating a modified example of the microlenses.

FIG. 16 is a cross-sectional view for illustrating a modified example of the microsenses.

FIG. 17 is a cross-sectional view for illustrating a modified example of the microlens array.

FIG. 18 is a cross-sectional view for illustrating a modified example of the display device.

FIG. 19 is a cross-sectional view for illustrating a modified example of the display device.

FIG. 20 is a cross-sectional view for illustrating a modified example of the display device.

FIG. 21 is a cross-sectional view for illustrating a modified example of the display device.

FIG. 22 is a cross-sectional view for illustrating a modified example of the display device.

FIG. 23A and FIG. 23B are cross-sectional views each explaining a modified example of the step of forming the microlens array.

FIG. 24A and FIG. 24B are cross-sectional views each explaining a modified example of the step of forming; the microlens array.

FIG. 25 is a plan view for illustrating an example of a schematic configuration of a module.

FIG. 26A is a front view for illustrating an example of an appearance of a digital still camera. FIG. 26B is a rear view for illustrating an example of an appearance of the digital still camera.

FIG. 27 is a perspective view for illustrating an example of an appearance of a head-mounted display.

FIG. 28 is a perspective view for illustrating an example of an appearance of a television device.

FIG. 29 is a perspective view for illustrating an example of an appearance of a lighting device.

FIG. 30 is a cross-sectional view of an analysis model A.

FIG. 31 is a cross-sectional view of an analysis model B.

FIG. 32 is a cross-sectional view of an analysis model C.

FIG. 33 is a cross-sectional view of an analysis model D.

FIG. 34 is a cross-sectional view of an analysis model E.

FIG. 35 is a graph for illustrating analysis results of test examples 1-1 to 1-8.

FIG. 36 is a graph for illustrating analysis results of test examples 2-1 to 2-10.

FIG. 37 is a graph for illustrating analysis results of test examples 3-1 to 3-4.

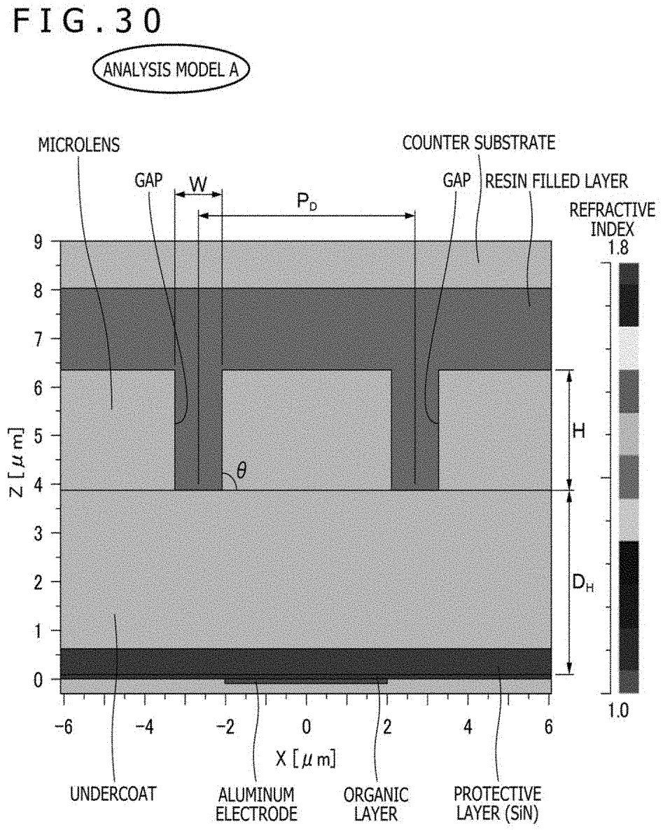

FIG. 30 is a graph for illustrating analysis results of teat examples 4-1 to 4-6.

FIG. 39 is a graph for illustrating analysis results of test examples 5-1 to 5-10.

### DESCRIPTION OF EMBODIMENT

An embodiment of the present disclosure will be described in the following order. It should be noted that the same or corresponding portions will be followed by the same reference signs in all the drawings of the following embodiment.

1 Configuration of display device

2 Manufacturing method of display device

3 Effect

4 Modified example

5 Application example

### 1 CONFIGURATION OF DISPLAY DEVICE

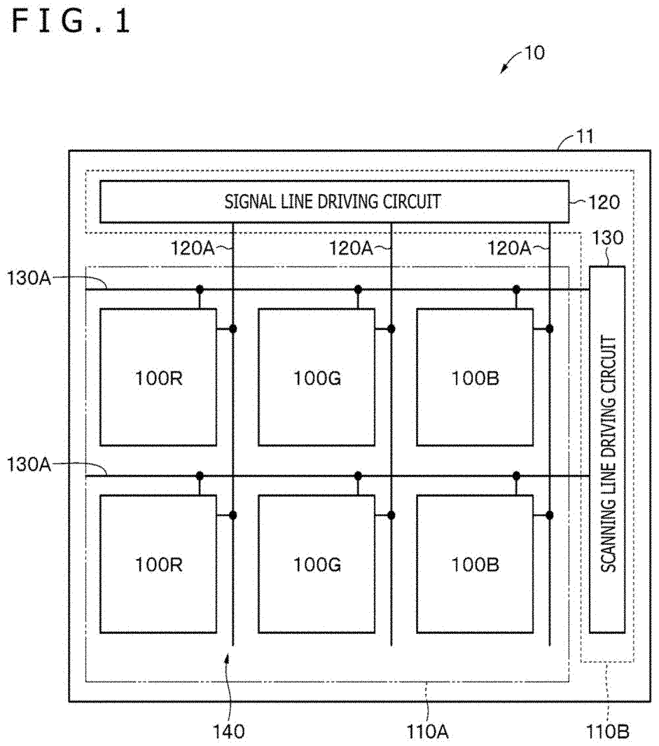

FIG. 1 illustrates an example of an entire configuration of a display device 10 according to an embodiment of the present disclosure. The display device 10 is suitable for use in various kinds of electronic apparatuses, and a display region 110A and a peripheral region 110B on a peripheral edge of the display region 110A are provided on a substrate 11. In the display region 110A, plural subpixels 100R, 100G, and 100B are arranged in a matrix. The subpixels 100R display a red color, the subpixels 100G display a green color, and the subpixels 100B display a blue color. It should be noted that, in a case where the subpixels 100R, 100G, and 100B are not particularly distinguished from one another, they are referred to as subpixels 100 in the following description.

Columns of the subpixels 100R, 100G, and 100B displaying the same colors are repeatedly arranged in the row direction. Therefore, a combination of three subpixels 100R, 100G, and 100B arranged in the row direction configures one pixel. A signal line driving circuit 120 and a scanning line driving circuit 130 that are drivers for video display are provided in the peripheral region 110B.

The signal line driving circuit 120 supplies a signal voltage of a video signal in accordance with luminance information supplied from a signal supply source (not illustrated), to a selected pixel via a signal line 120A. The scanning line driving circuit 130 is configured using shift registers and the like that sequentially shift (transfer) start pulses in synchronization with clock pulses to be input. The scanning line driving circuit 130 scans the pixels on a row basis when writing a video signal to each pixel, and sequentially supplies a scanning signal to each scanning line 130A.

The display device 10 is, for example, a microdisplay in which self light-emitting elements such as OLEDs, Micro-OLEDs, or Micro-LEDs are formed in an array. The display device 10 is suitable for use in a display device for VR (Virtual Reality), MR (Mixed Reality), or AR (Augmented Reality), an electronic view finder (EVF), a small projector, or the like.

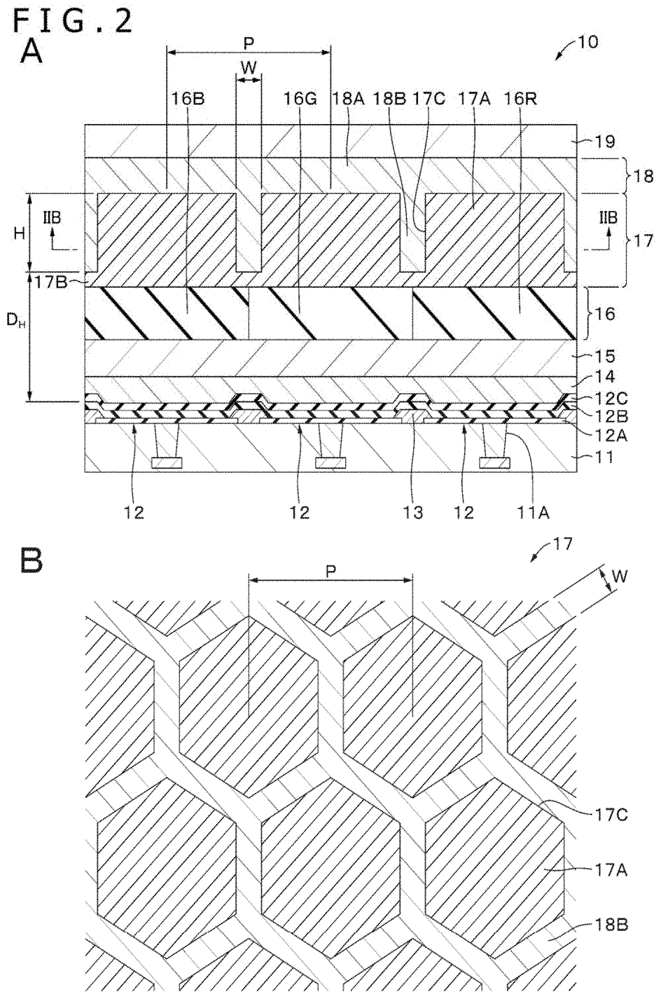

FIG. 2 illustrates cross-sectional views each illustrating an example of a configuration of the display device 10 according to the embodiment of the present disclosure. The display device 10 is a top-emission display device, and includes a substrate (first substrate) 11 having a principal surface, plural light-emitting elements 12 and insulating layers 13 provided on the principal surface of the substrate 11, a protective layer 14 provided on the plural light-emitting elements 12, an undercoat layer 15 provided on the protective layer 14, a color filter 16 provided on the undercoat layer 15, a microlens array 17 provided on the color filter 16, a resin filled layer (upper layer) 18 provided on the microlens array 17, and a counter substrate (second substrate) 19 provided on the resin filled layer 18. It should be noted that the counter substrate 19 side is the top side, and the substrate 11 side is the bottom side.

The plural light-emitting elements 12 are arranged in a matrix on the principal surface of the substrate 11. The light-emitting elements 12 are white OLEDs, and a method using the white OLEDs and the color filter 16 is used as a method of coloring in the display device 10. It should be noted that the method of coloring is not limited thereto, and an RGB separate coloring method or the like may be used. In addition, a monochromatic filter may be used. In addition, the light-emitting elements 12 may also be Micro-OLEDs (MOLEDs) or Micro-LEDs.

Each of the light-emitting elements 12 is obtained by stacking a first electrode 12A as, for example, an anode, an organic layer 12B, and a second electrode 12C as, for example, a cathode in this order from the substrate 11 side.

The substrate 11 is a support for supporting the plural light-emitting elements 12 arrayed on the principal surface. In addition, although not illustrated in the drawing, the substrate 11 may be provided with a driving circuit including a sampling transistor and a driving transistor for controlling driving of the plural light-emitting elements 12, and a power supply circuit for supplying electric power to the plural light-emitting elements 12.

The substrate 11 may be configured using, for example, glass or resin having low permeability of moisture and oxygen, or may be formed using a semiconductor that can easily form a transistor and the like. Specifically, the substrate 11 may be a glass substrate such as high strain point glass, soda glass, borosilicate glass, forsterite, lead glass, or quartz glass, a semiconductor substrate such as amorphous silicon or polycrystalline silicon, a resin substrate such as polymethyl methacrylate, polyvinyl alcohol, polyvinyl phenol, polyether sulfone, polyimide, polycarbonate, polyethylene terephthalate, or polyethylene naphthalate, or the like.

The substrate 11 is provided with a contact plug 11A. The contact plug 11A electrically connects the first electrode 12A to the driving circuit, the power supply circuit, and the like. Specifically, the contact plug 11A electrically connects the first electrode 12A to the driving circuit, the power supply circuit, and the like (not illustrated) provided inside the substrate 11, and applies electric power for emitting light from the light-emitting elements 12 to the first electrode 12A. The contact plug 11A may be formed using, for example, a single metal, an alloy, or the like such as chromium (Cr), gold (Au), platinum (Pt), nickel (Ni), copper (Cu), molybdenum (Mo), tungsten (W), titanium (Ti), tantalum (Ta), aluminum (Al), iron (Fe), or silver (Ag), and may be formed by laminating plural these metal films.

### (First Electrode)

The first electrodes 12A are provided by being electrically separated for each of the subpixels 100R, 100G, and 100B. Each of the first electrodes 12A also functions as a reflective layer, and is preferably configured using a metal layer having reflectivity as high as possible and a large work function in order to enhance the light-emitting efficiency. As the constituent material of the metal layer, for example, at least one kind among single metals and alloys of metallic elements such as chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag) can be used. Specific examples of the alloys include an AlNi alloy, an AlCu alloy, and the like. Each of the first electrodes 12A may be formed using a laminated film of plural metal layers including at least one kind among the single metals and alloys of the above metallic elements.

### (Second Electrode)

Each of the second electrodes 12C is provided in the display region 110A as an electrode common to all the subpixels 100R, 100G, and 100B. Each of the second electrodes 12C is a transparent electrode having permeability for light generated in the organic layer 12B. Here, it is assumed that the transparent electrode also includes a semipermeable reflective film. Each of the second electrodes 12C is configured using, for example, a metal or metal oxide. As the metal, for example, at least one kind among single metals and alloys of metallic elements such as aluminum (Al), magnesium (Mg), calcium (Ca), and sodium (Na) can be used. As the alloy, for example, an alloy (MgAg alloy) of magnesium (Mg) and silver (Ag) or an alloy (AlLi alloy) of aluminum (Al) and lithium (Li) is preferable. As the metal oxide, for example, metal oxide such as a mixture (ITO) of indium oxide and tin oxide, a mixture (IZO) of indium oxide and zinc oxide, or zinc oxide (ZnO) can be used.

### (Insulating Layer)

Each of the insulating layers 13 is for electrically separating the first electrodes 12A for each of the subpixels 100R, 100G, and 100B. Each of the insulating layers 13 is provided between the first electrodes 12A and covers the peripheral edge portions of the first electrodes 12A. More specifically, each of the insulating layers 13 has an opening at a portion corresponding to each first electrode 12A, and covers the peripheral edge portions of the first electrodes 12A from the peripheral edge portion of an upper surface (a surface facing the second electrode 12C) of each first electrode 12A to a side surface (end surface) of each first electrode 12A.

Each of the insulating layers 13 is configured using, for example, an organic material or an inorganic material. The organic material includes, for example, polyimide, an acrylic resin, or the like. The inorganic material includes, for example, silicon oxide, silicon nitride, silicon oxynitride, aluminum oxide, or the like.

### (Organic Layer)

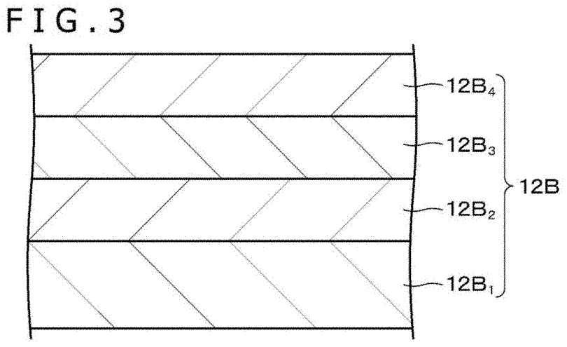

The organic layer 12B is provided in the display region 110A as an organic layer common to all the subpixels 100R, 100G, and 100B. FIG. 3 is an enlarged view of the organic layer 12B illustrated in FIG. 2. The organic layer 12B has a configuration in which a hole injection layer 12B₁, a hole transport layer 12B₂, a light-emitting layer 12B₃, and an electron transport layer 12B₄ are laminated in this order from the first electrode 12A side. It should be noted that the configuration of the organic layer 12B is not limited thereto, and layers other than the light-emitting layer 12B₃ are provided as necessary.

The hole injection layer 12B₁ is a buffer layer for enhancing hole injection efficiency into the light-emitting layer 12B₃ and for suppressing leakage. The hole transport layer 12B₂ is for enhancing hole transport efficiency into the light-emitting layer 12B₃. The light-emitting layer 12B₃ applies an electric field to cause recombination of electrons and holes, and generates light. The electron transport layer 12B₄ is for enhancing electron transport efficiency into the light-emitting layer 12B₃. An electron injection layer (not illustrated) may be provided between the electron transport layer 12B₄ and the second electrode 12C. The electron injection layer is for enhancing electron injection efficiency.

### (Protective Layer)

The protective layer 14 is for blocking the light-emitting elements 12 from the outside air to suppress the intrusion of moisture into the inside of the light-emitting elements 12 from the outside environment. In addition, in a case where the second electrodes 12C are configured using metal layers, the protective layer 14 also has a function of suppressing oxidation of the metal layers.

The protective layer 14 is configured using, for example, an inorganic material having low hygroscopicity such as silicon oxide (SiOₓ), silicon nitride (SiNₓ), silicon oxide nitride (SiNₓO_{y}), titanium oxide (TiOₓ), or aluminum oxide (AlₓO_{y}). In addition, the protective layer 14 may have a single-layer structure, or may have a multi-layer structure in a case where the thickness is to be increased. This is to relax the internal stress in the protective layer 14. In addition, the protective layer 14 may be configured using a polymer resin. In this case, at least one kind of resin material of a thermosetting resin and an ultraviolet curing resin can be used as the polymer resin.

### (Undercoat Layer)

For example, the undercoat layer 15 is for planarizing a step of the protective layer 14. The undercoat layer 15 is configured using, for example, a polymer resin. In this case, at least one kind of resin material of a thermosetting resin and an ultraviolet curing resin can be used as the polymer resin. It should be noted that the undercoat layer 15 is provided as necessary, and does not need to be provided.

### (Color Filter)

The color filter 16 is, for example, an on-chip color filter (OCCF). The color filter 16 includes, for example, a red filter 16R, a green filter 16G, and a blue filter 16B. The red filter 16R, the green filter 16G, and the blue filter 16B are provided opposite to the light-emitting element 12 of the subpixel 100R, the light-emitting element 12 of the subpixel 100G, and the light-emitting element 12 of the subpixel 100B, respectively. Accordingly, white light emitted from each light-emitting element 12 in the subpixel 100R, the subpixel 100G, and the subpixel 100B passes through the red filter 16R, the green filter 16G, and the blue filter 16B, and thus each of red light, green light, and blue light is emitted from the display surface. In addition, a light shielding layer (not illustrated) may be provided at a region between the color filters of the respective colors, that is, between the subpixels 100.

### (Microlens)

The microlens array 17 is a light extraction structure for improving the light extraction efficiency of the display device 10. The microlens array 17 includes a base bottom portion 17B and plural microlenses 17A provided on the base bottom portion 17B. Each of the microlenses 17A is, for example, an on-chip microlens (OCL), and is a structure having side surfaces vertical to the principal surface of the substrate 11. It is preferable that the top surface of each of the microlenses 17A be planar. In the embodiment, each of the microlenses 17A has a hexagonal columnar shape. The plural microlenses 17A are two-dimensionally arrayed in the in-plane direction of the principal surface of the substrate 11, and configures a honeycomb structure. The microlenses 17A are provided corresponding to the light-emitting elements 12, and the materials of the microlenses 17A are the same irrespective of each light-emitting element 12.

A gap 17C is provided between the side surfaces of the adjacent microlenses 17A. The gap 17C is filled with a filled resin 18A. The refractive index n₂ of the filled resin 18A filled between the microlenses 17A is lower than the refractive index n₁ of the microlenses. That is, the refractive index n₂ between the microlenses 17A is lower than the refractive index n₁ of the microlenses 17A.

Each of the microlenses 17A is provided opposite to the light-emitting element 12 of the subpixel 100R, the light-emitting element 12 of the subpixel 100G, and the light-emitting element 12 of the subpixel 100B. Accordingly, white light emitted from each light-emitting element 12 in the subpixel 100R, the subpixel 100G, and the subpixel 100B is condensed by the microlenses 17A toward the front of the display device 10, and is emitted from the display surface. Therefore, the utilization efficiency of light in the front direction is enhanced.

The microlens array 17 is configured using, for example, an inorganic material or a polymer resin transparent to each color light emitted from the color filter 16. As the inorganic material, for example, silicon oxide (SiO₂) can be used. As the polymer resin, for example, a photosensitive resin can be used.

The height H of each microlens 17A is preferably 1.5 μm or more and 2.5 μm or less. When the height H of each microlens 17A is 1.5 μm or more, the light condensing effect in the vicinity of the outer periphery of each light-emitting element 12 can be effectively enhanced.

The width (width of a portion between the microlenses 17A) W of the gap 17C between the microlenses 17A is preferably 0.4 μm or more and 1.2 μm or less, more preferably 0.6 μm or more and 1.2 μm or less, still more preferably 0.8 μm or more and 1.2 μm or less, and particularly, preferably 0.8 μm or more and 1.0 μm or less. When the width W between the microlenses 17A is 0.4 μm or more, the width W between the microlenses 17A can be made equal to or larger than the lower limit value of the wavelength band of visible light, and thus the deterioration of the function of the gap 17C can be suppressed. Therefore, the light condensing effect in the vicinity of the outer periphery of each light-emitting element 12 can be effectively enhanced. On the other hand, when the width W between the microlenses 17A is 1.2 μm or less, the reduction of the size of each microlens 17A with respect to the light-emitting elements 12 can be suppressed. Therefore, the light condensing effect in the vicinity of the outer periphery of each light-emitting element 12 can be effectively enhanced.

The pitch P of the microlenses 17A is preferably 1 μm or more and 10 μm or less. When the pitch P of the microlenses 17A is 10 μm or less, the wave behavior of light is remarkably expressed, and thus the effect of using the microlenses 17A having the above-described configuration is remarkably exhibited.

The distance D_{H} between the light-emitting elements 12 and the microlenses 17A is preferably more than 0.35 μm and 7 μm or less, more preferably 1.3 μm or more and 7 μm or less, still more preferably 2.8 μm or more and 7 μm or less, and particularly, preferably 3.8 μm or more and 7 μm or less. When the distance D_{H} between the light-emitting elements 12 and the microlenses 17A exceeds 0.35 μm, the light condensing effect in the vicinity of the outer periphery of each light-emitting element 12 can be efficiently enhanced. On the other hand, when the distance D_{H} between the light-emitting elements 12 and the microlenses 17A is 7 μm or less, the deterioration of the viewing angle characteristic can be suppressed.

### (Resin Filled Layer)

The resin filled layer 18 has a function as an adhesive layer for causing the microlens array 17 to adhere to the counter substrate 19. In addition, the resin filled layer 18 also has a function as a filler for filling the gap 17C between the microlenses 17A. The resin filled layer 18 is configured using the filled resin 18A filled in a space between the microlens array 17 and the counter substrate 19 and a filled resin 18B filled in the gap 17C between the microlenses 17A. The filled resin 18A is an example of an upper layer provided on the plural microlenses 17A, and the refractive index n₃ of the filled resin 18A is preferably lower than the refractive index n₁ of the structure. Accordingly, the light condensing effect in the vicinity of the outer periphery of each light-emitting element 12 can be effectively enhanced. The resin filled layer 18 is configured using, for example, at least one kind of resin material of a thermosetting resin and an ultraviolet curing resin. It should be noted that the filled resin 18A and the filled resin 18B may be configured using different materials, and in this case, the refractive index n₃ of the filled resin 18A and the refractive index n₂ of the filled resin 18B may be different from each other.

### (Counter Substrate)

The counter substrate 19 is provided such that the principal surface of the counter substrate 19 and the principal surface of the substrate 11 provided with the plural light-emitting elements 12 face each other. The counter substrate 19 seals the light-emitting elements 12, the color filter 16, the microlens array 17, and the like together with the resin filled layer 18. The counter substrate 19 is configured using a material such as glass transparent to each color light emitted from the color filter 16.

### 2 MANUFACTURING METHOD OF DISPLAY DEVICE

Hereinafter, a manufacturing method of the display device 10 having the above-described configuration will be described.

First, a driving circuit and the like are formed on the principal surface of the substrate 11 by using, for example, a thin film forming technique, a photolithography technique, and an etching technique. Next, a metal layer is formed on the driving circuit and the like by, for example, a sputtering method, and then the metal layer is patterned by using, for example, a photolithography technique and an etching technique, thereby forming the plural first electrodes 12A separated for each light-emitting element 12 (that is, for each subpixel 100).

Next, the insulating layer 13 is formed by, for example, a CVD method. Next, the insulating layer 13 is patterned by using a photolithography technique and an etching technique. Next, the hole injection layer 12B₁, the hole transport layer 12B₂, the light-emitting layer 12B₃, and the electron transport layer 12B₄ are laminated in this order on the first electrode 12A and the insulating layer 13 by, for example, a vapor deposition method, thereby forming the organic layer 12B. Next, the second electrode 12C is formed on the organic layer 12B by, for example, a sputtering method. Accordingly, the plural light-emitting elements 12 are formed on the principal surface of the substrate 11.

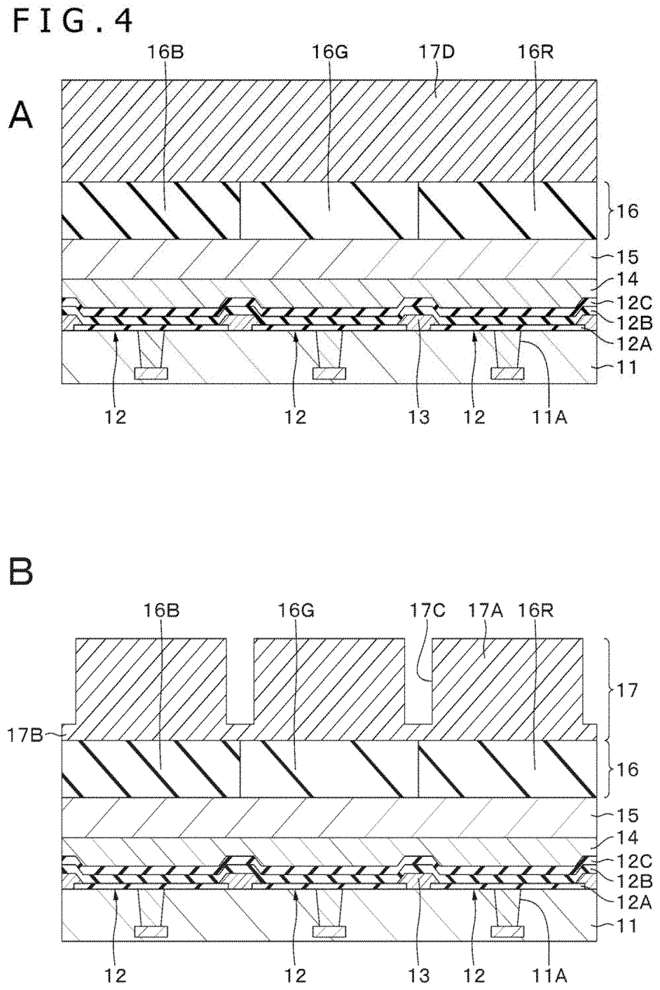

Next, the protective layer 14 is formed on the second electrode 12C by, for example, a vapor deposition method or a CVD method. Next, the undercoat layer 15 is formed on the protective layer 14 by, for example, a spin coat method, and then the color filter 16 is formed on the undercoat layer 15 by using, for example, a thin film forming technique, a photolithography technique, and an etching technique. Next, as illustrated in FIG. 4A, a photosensitive resin is applied onto the color filter 16 to form a photosensitive resin layer 17D, and then the gap 17C is formed in the photosensitive resin layer 17D by using a photolithography technique to form the microlens array 17 as illustrated in FIG. 4B.

Next, the microlens array 17 is covered with the resin filled layer 18 by, for example, an ODF (One Drop Fill) method, and then the counter substrate 19 is placed on the resin filled layer 18. Next, the substrate 11 and the counter substrate 19 are bonded to each other through the resin filled layer 18 by, for example, applying heat to the resin filled layer 18 or irradiating the resin filled layer 18 with ultraviolet rays to cure the resin filled layer 18. Accordingly, the display device 10 is sealed. It should be noted that, in a case where the resin filled layer 18 contains both a thermosetting resin and an ultraviolet curing resin, the resin filled layer 18 is temporarily cured by irradiation with ultraviolet rays, and then the resin filled layer 18 may be completely cured by heat applied thereto.

### 3 EFFECT

The display device 10 according to the above-described embodiment includes the plural microlenses 17A respectively provided on the plural light-emitting elements 12. Each of the microlenses 17A has side surfaces vertical to the principal surface of the substrate 11, and the refractive index n₂ between the microlenses 17A is lower than the refractive index n₁ of the microlenses 17A. Accordingly, the light condensing effect in the vicinity of the outer periphery of each light-emitting element (light source) 12 can be improved as compared to a hemispherical microlens. Therefore, the efficiency of the display device 10 can be enhanced. That is, the high luminance and low power consumption of the display device 10 can be realized.

The display device 10 according to the above-described embodiment can be manufactured without using a reflow, a gray tone mask, or the like because the microlenses 17A have the vertical side surfaces. Therefore, the manufacturing process can be simplified as compared to a hemispherical microlens or the like.

In a case of a general microlens (for example, a hemispherical microlens), if the distance between the microlenses and the light-emitting elements (light sources) is not made long, it is difficult to enhance the efficiency of the display device. In addition, if the distance between the microlenses and the light-emitting elements (light sources) is made long in order to enhance the efficiency of the display device, there is also a problem that the viewing angle characteristic deteriorates. On the contrary, in the display device 10 according to the above-described embodiment, even if the distance between the microlenses 17A that are light extraction structures and the light-emitting elements (light sources) 12 is not made long, the efficiency of the display device 10 can be enhanced. Therefore, the efficiency of the display device 10 can be enhanced while the deterioration of the viewing angle characteristic is being suppressed.

### 4 MODIFIED EXAMPLE

### Modified Example 1

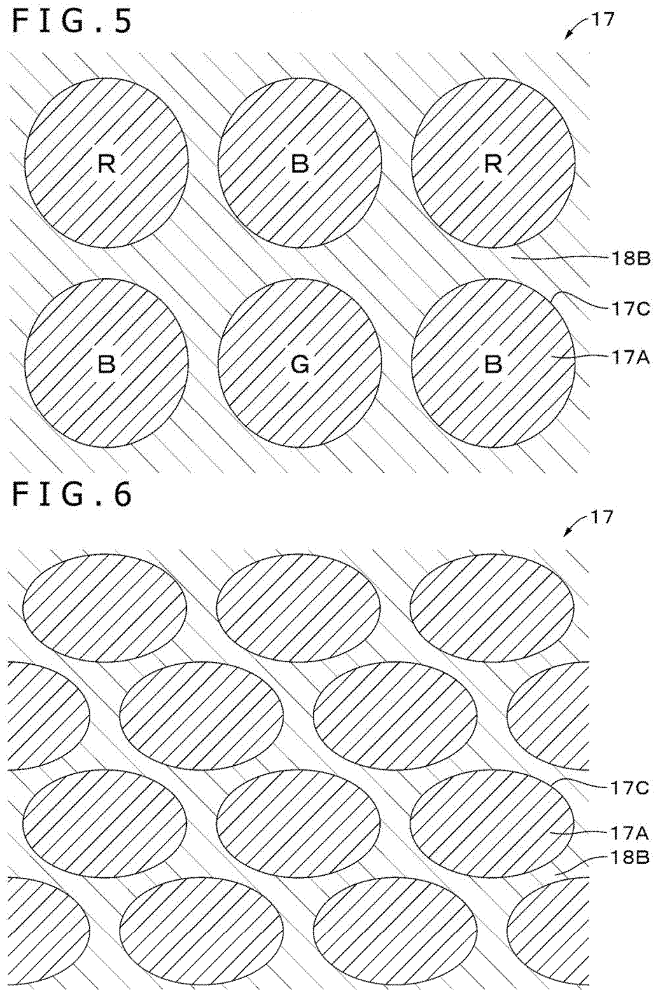

In the above-described embodiment, the case (see FIG. 2B) in which each microlens 17A has a hexagonal columnar shape has been described, but the shape of each microlens 17A is not limited thereto, and each microlens 17A may have a columnar shape other than a hexagonal columnar shape or a substantially columnar shape. Hereinafter, an example of the shape of each microlens 17A other than a hexagonal columnar shape will be described with reference to FIG. 5 to FIG. 8.

As illustrated in FIG. 5, each microlens 17A may have a cylindrical shape. Since each microlens 17A has a cylindrical shape, the filling property of the filled resin 18B with respect to the gap 17C can be improved.

As illustrated in FIG. 6, each microlens 17A may have an elliptical columnar shape. Since each microlens 17A has an elliptical columnar shape, the filling property of the filled resin 18B with respect to the gap 17C can be improved. It is preferable that the plural microlenses 17A be arranged such that the major axis of the elliptical shape of each cross section thereof corresponds to the horizontal direction of the display surface and the minor axis thereof corresponds to the vertical direction of the display surface. The viewing angle characteristic in the horizontal direction can be improved by arranging the plural microlenses 17A as described above.

As illustrated in FIG. 7, each microlens 17A may have a rectangular columnar shape (rectangular parallelepiped shape). In this case, the side surfaces having the rectangular shape of the adjacent microlenses 17A are arranged in parallel to each other. The bottom surface and the top surface of each microlens 17A may have, for example, a square shape.

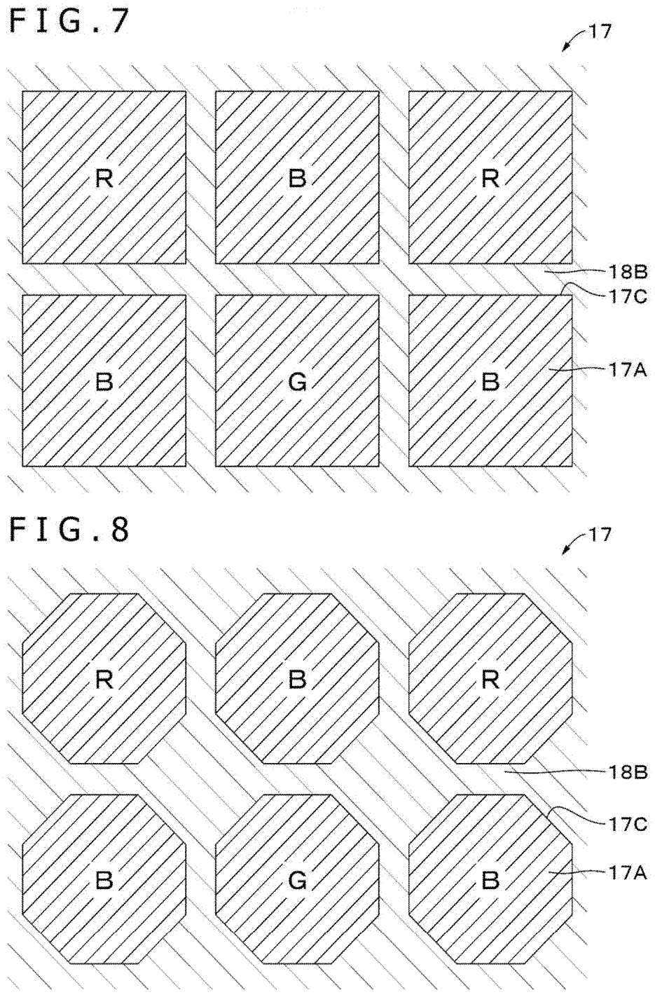

As illustrated in FIG. 8, each microlens 17A may have an octagonal columnar shape. In this case, the side surfaces having the rectangular shape of the adjacent microlenses 17A are arranged in parallel to each other. Since each microlens 17A has an octagonal columnar shape, the filling property of the filled resin 18B with respect to the gap 17C can be improved. It should be noted that each microlens may have a prismatic columnar shape other than a rectangular columnar shape, a hexagonal columnar shape, and an octagonal columnar shape.

### Modified Example 2

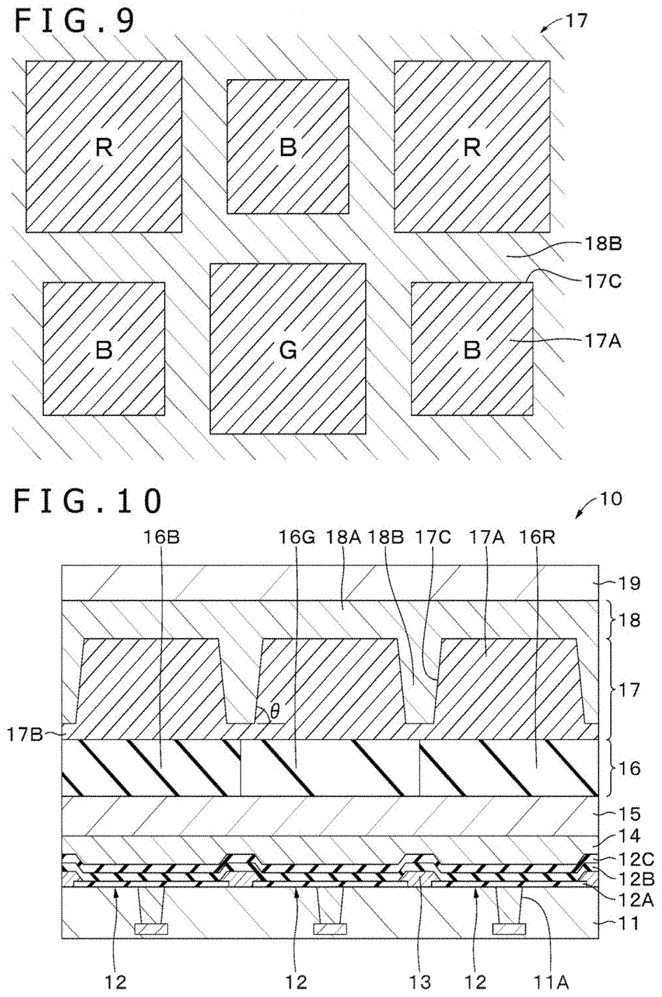

In the above-described embodiment, the case (see FIG. 2A and FIG. 2B) in which the sizes of the microlenses 17A configuring the microlens array 17 are the same has been described, but the sizes of the microlenses 17A provided on the red filters 16R, the microlenses 17A provided on the green filters 16G, and the microlenses 17A provided on the blue filters 16B may be different from each other as illustrated in FIG. 9. It should be noted that although FIG. 9 illustrates a configuration in which each microlens 17A has a rectangular columnar shape, the sizes of the microlenses 17A may be different from each other as described above even in a case where each microlens 17A has a shape other than a rectangular columnar shape.

### Modified Example 3

In the above-described embodiment, the case in which the refractive index n₁ of each microlens 17A configuring the microlens array 17 is the same has been described, but the refractive indexes of the microlenses 17A provided on the red filters 16R, the microlenses 17A provided on the green filters 16G, and the microlenses 17A provided on the blue filters 16B may be different from each other.

In a case where the refractive indexes of the microlenses 17A provided on the red filters 16R, the microlenses 17A provided on the green filters 16G, and the microlenses 17A provided on the blue filters 16B are n₁₁, n₁₂, and n₁₃, respectively, and the refractive index between the microlenses 17A (that is, the refractive index of the filled resin 18A filled between the microlenses 17A) is n₂, the refractive indexes n₁₁, n₁₂, n₁₃, and n₂ satisfy the relationship of n₁₁, n₁₂, n₁₃, >n₂.

### Modified Example 4

In the above-described embodiment, the case (see FIG. 2A) in which each microlens 17A is a structure having the side surfaces vertical to the principal surface of the substrate 11 has been described, but each microlens 17A may be a structure having side surfaces substantially vertical to the principal surface of the substrate 11. Hereinafter, an example of a case where the structure has the substantially vertical side surfaces will be described.

As illustrated in FIG. 10, the side surfaces of the microlenses 17A are inclined such that the width of each microlens 17A becomes narrower from the bottom surface toward the top surface of each microlens 17A, and each microlens 17A may have, for example, a cone shape. The inclined side surfaces may be planar or curved in a protruding or recessed shape.

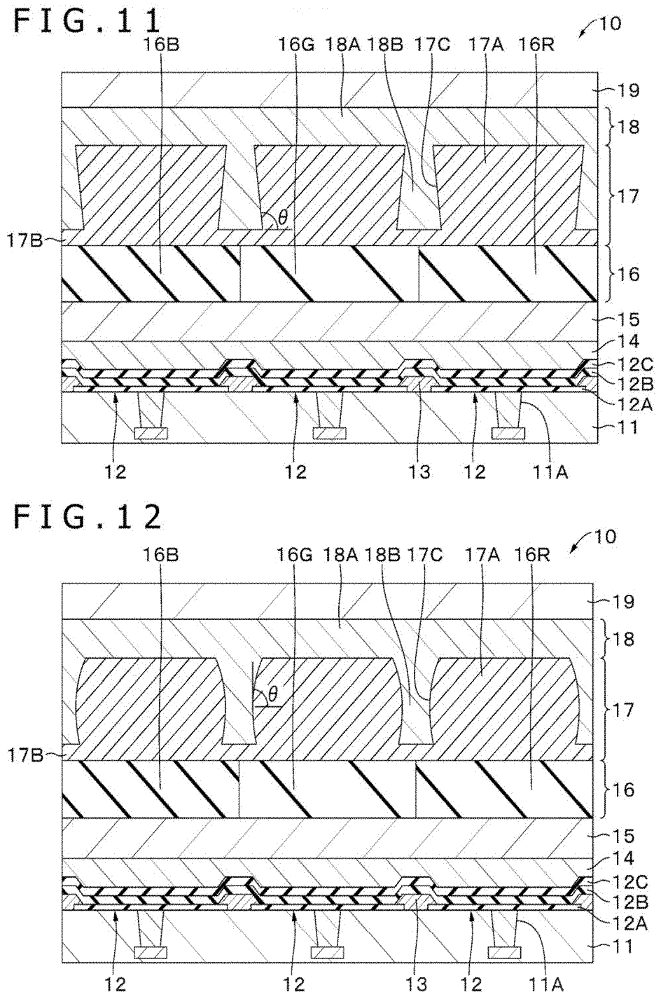

As illustrated in FIG. 11, the side surfaces of the microlenses 17A are inclined such that the width of each microlens 17A becomes wider from the bottom surface toward the top surface of each microlens 17A, and each microlens 17A may have, for example, an inverted cone shape. The inclined side surfaces may be flat or curved in a protruding or recessed shape.

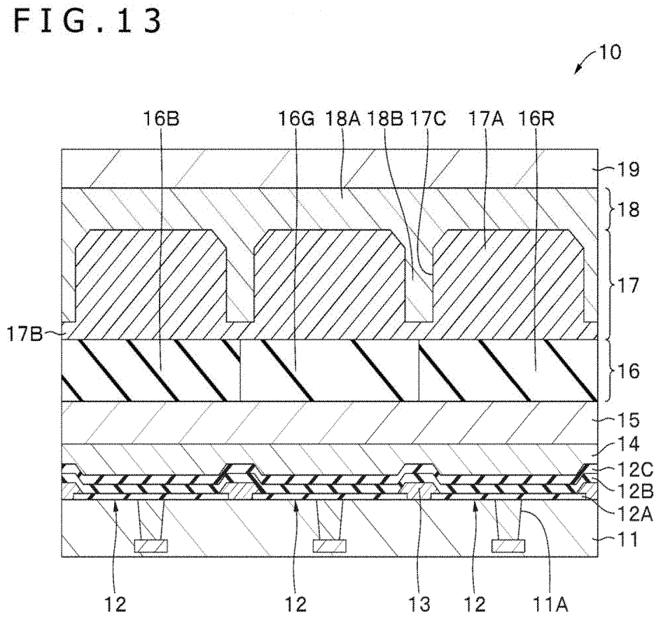

As illustrated in FIG. 12, the side surfaces of the microlenses 17A may be curved in a protruding shape. Alternatively, the side surfaces of the microlenses 17A may be curved in a recessed shape.

It should be noted that, in the shape examples illustrated in FIG. 10 and FIG. 11, the inclined angle θ of the side surfaces with respect to the principal surface of the substrate 11 is in the range of 80 to 100 degrees. In a case where the side surfaces are curved in a protruding or recessed shape, the tangent line of the cross section of each microlens 17A is preferably in the range of 80 to 100 degrees. Here, the “cross section of each microlens 17A” means a cross section obtained by cutting each microlens 17A vertically with respect to the principal surface of the substrate 11.

In order to efficiently enhance the light condensing effect in the vicinity of the outer periphery of each light-emitting element 12, the inclined angle θ of the side surfaces with respect to the principal surface of the substrate 11 is preferably 81.8 to 98.2 degrees, more preferably 84.0 to 96.0 degrees, still more preferably 86.0 to 94.0 degrees, particularly, preferably 88.0 to 92.0 degrees, and most preferably approximately 90 degrees.

As illustrated in FIG. 13, the side surfaces of the top portion of each microlens 17A are inclined such that the width of the top portion of each microlens 17A gradually becomes narrower toward the height direction of each microlens 17A, and the top portion of each microlens 17A may have, for example, a cone shape. The inclined side surfaces may be flat or curved in a protruding or recessed shape. Here, the “height direction of each microlens 17A” means the height direction of each microlens 17A directing from the bottom surface toward the top surface of each microlens 17A.

### Modified Example 5

In the above-described embodiment, the case (see FIG. 2A) in which each microlens 17A has the planar top surface has been described, but each microlens 17A may have a top surface curved in a protruding or recessed shape. However, from the viewpoint of improving luminance in the front direction, it is preferable that each microlens 17A have a planar top surface.

### Modified Example 6

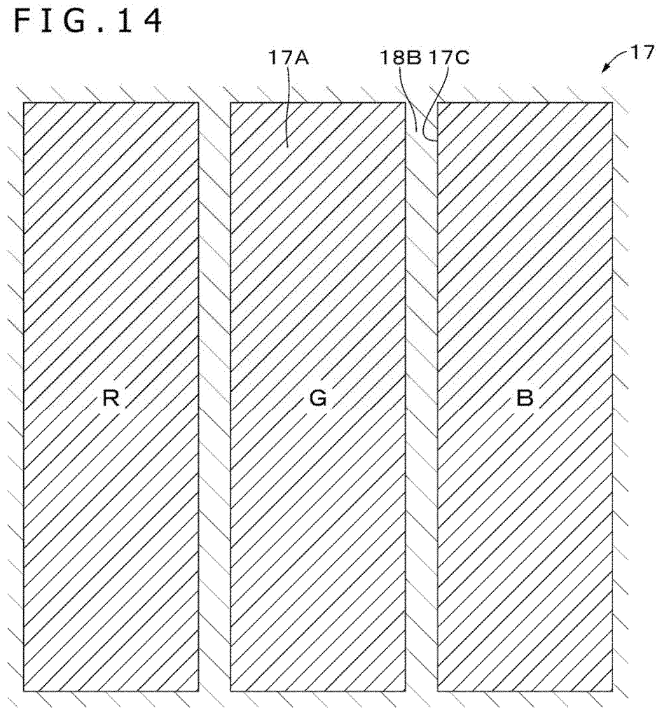

In the above-described embodiment, the case in which each subpixel 100 has a square shape has been described, but each subpixel 100 may have a rectangular shape. In this case, as illustrated in FIG. 14, rectangular parallelepiped lenses may be used as the microlenses 17A.

### Modified Example 7

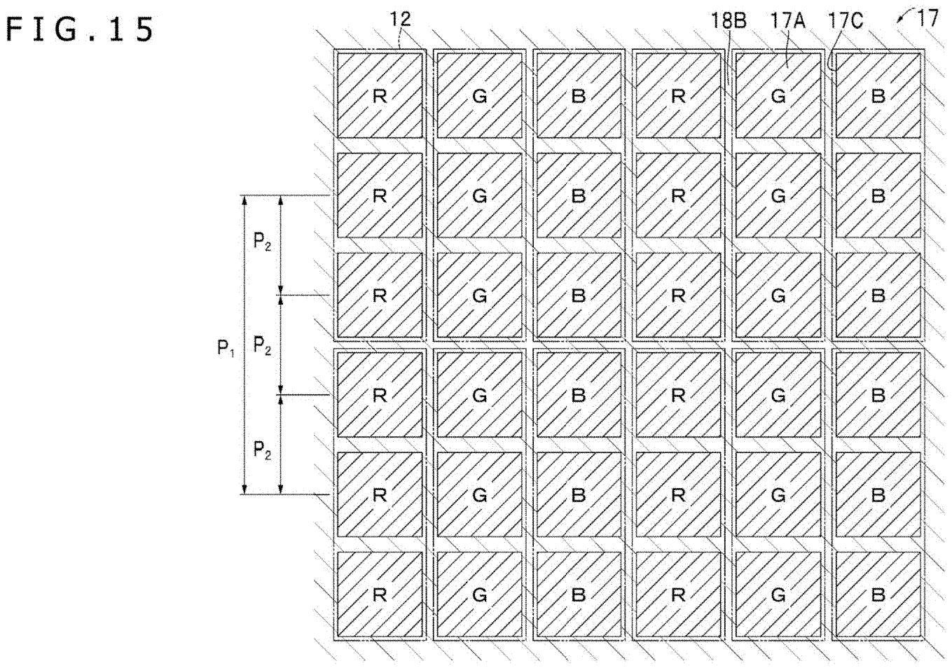

In the above-described embodiment, the case in which the pitches of the light-emitting elements 12 and the microlenses 17A are the same, that is, the case in which one microlens 17A is provided on each light-emitting element 12, has been described, but the arrangement form of the microlenses 17A is not limited thereto. For example, as illustrated in FIG. 15, a pitch P₁ of the light-emitting elements 12 in the vertical direction of the display surface may be three times a pitch P₂ of the microlenses 17A in the vertical direction of the display surface. That is, three microlenses 17A may be provided on one light-emitting element 12. It should be noted that although not illustrated in the drawing, the pitch P₁ of the light-emitting elements 12 in the vertical direction of the display surface may be twice the pitch P₂ of the microlenses 17A in the vertical direction of the display surface. That is, two microlenses 17A may be provided on one light-emitting element 12.

The pitch P₁ of the light-emitting elements 12 in the vertical direction (first direction) of the display surface may be n times or more (n is a positive integer) the pitch P₂ of the microlenses 17A in the vertical direction (first direction) of the display surface, and the pitch P₁ of the light-emitting elements 12 in the horizontal direction (second direction) of the display surface may be m times or more (m is a positive integer) the pitch P₂ of the microlenses 17A in the horizontal direction (second direction) of the display surface. That is, n×m pieces of microlenses 17A may be provided on one light-emitting element 12. The upper limit values of n and m are not particularly limited, but are, for example, 10 or less, 5 or less, or 3 or less.

### Modified Example 8

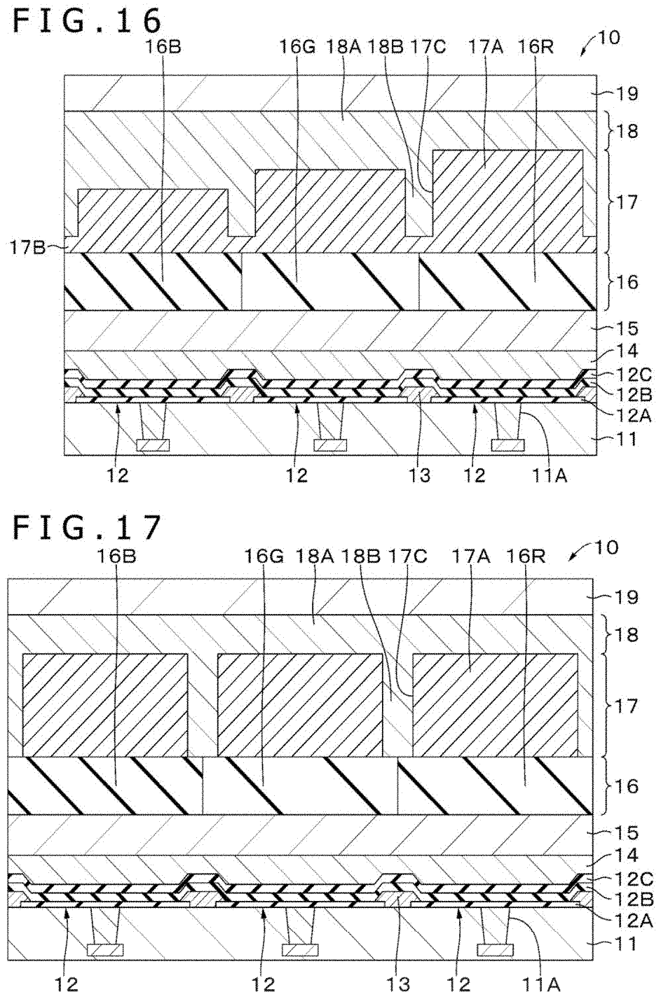

In the above-described embodiment, the configuration (see FIG. 2A) in which the heights of the microlenses 17A configuring the microlens array 17 are the same has been described, but the heights of the microlenses 17A provided on the red filters 16R, the microlenses 17A provided on the green filters 16G, and the microlenses 17A provided on the blue filters 16B may be different from each other as illustrated in FIG. 16.

### Modified Example 9

In the above-described embodiment, the configuration (see FIG. 2A) in which the microlens array 17 includes the base bottom portion 17B has been described, but the microlens array 17 does not need to include the base bottom portion 17B as illustrated in FIG. 17. That is, each microlens 17A may be independent. In this case, the microlenses 17A may be provided directly on the color filters 16.

### Modified Example 10

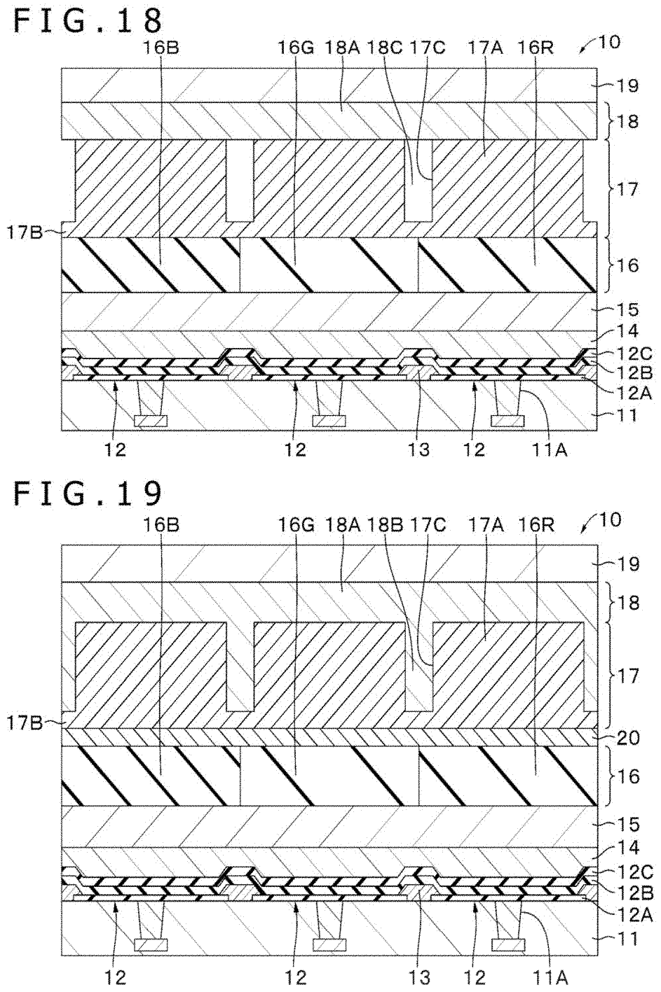

In the above-described embodiment, the configuration (see FIG. 2A) in which the gap 17C between the microlenses 17A is filled with the filled resin 18B has been described, but it is only required that the refractive index n₂ of a portion between the microlenses 17A be lower than the refractive index n₁ of the microlenses 17A, and the present disclosure is not limited to the above configuration. For example, as illustrated in FIG. 18, the gap 17C between the microlenses 17A may be a space 18C filled with gas such as air.

### Modified Example 11

In the above-described embodiment, the configuration (see FIG. 2A) in which the microlens array 17 is provided directly on the color filter 16 has been described, but an undercoat layer 20 may be further provided between the color filters 16 and the microlens array 17 as illustrated in FIG. 19. For example, the undercoat layer 20 is for planarizing a step due to a difference between the film thicknesses of the color filters 16. The undercoat layer 20 is configured using, for example, a material similar to that of the undercoat layer 15 in the above-described embodiment.

### Modified Example 12

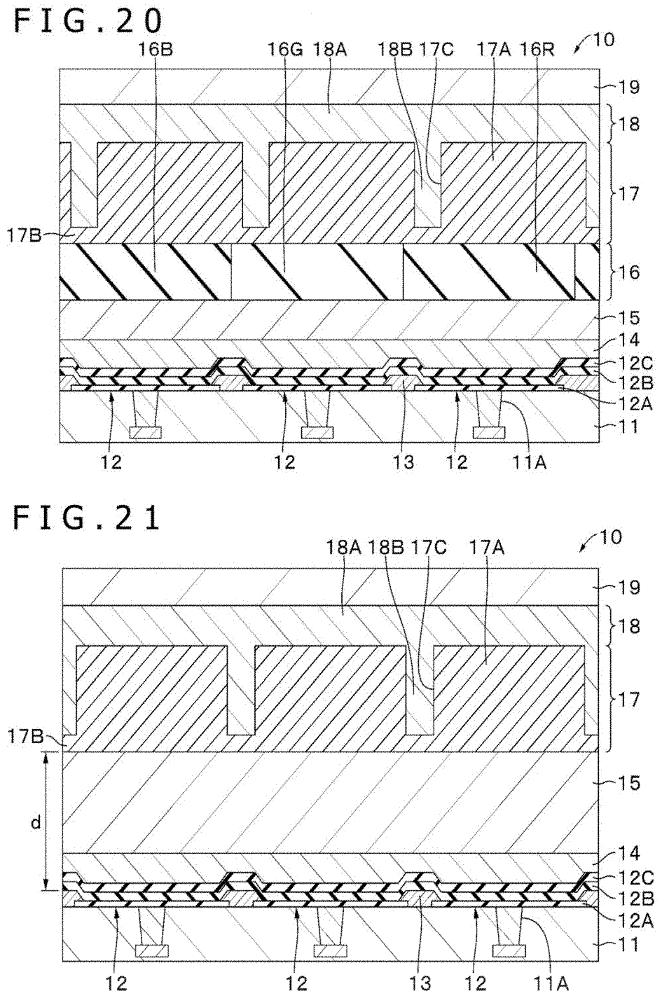

In the above-described embodiment, the configuration (see FIG. 2A) in which the optical axis (center axis) of each microlens 17A matches the center of the red filter 16R, the green filter 16G, or the blue filter 16B has been described, but the optical axis (center axis) of each microlens 17A may be deviated from the center of the red filter 16R, the green filter 16G, or the blue filter 16B as illustrated in FIG. 20.

### Modified Example 13

In the above-described embodiment, the configuration (see FIG. 2A) in which the display device 10 includes the color filter 16 has been described, but the display device 10 does not need to include the color filter 16 as illustrated in FIG. 21. The distance d between the organic layer 12B and the microlenses 17A is, for example, 2 μm or more and 5 μm or less. In a case of the above configuration, as the plural light-emitting elements 12, monochromatic light-emitting elements may be used, or plural kinds of light-emitting elements (for example, three kinds of light-emitting elements such as red light-emitting elements, green light-emitting elements, and blue light-emitting elements) that emits light having different wavelengths may be used.

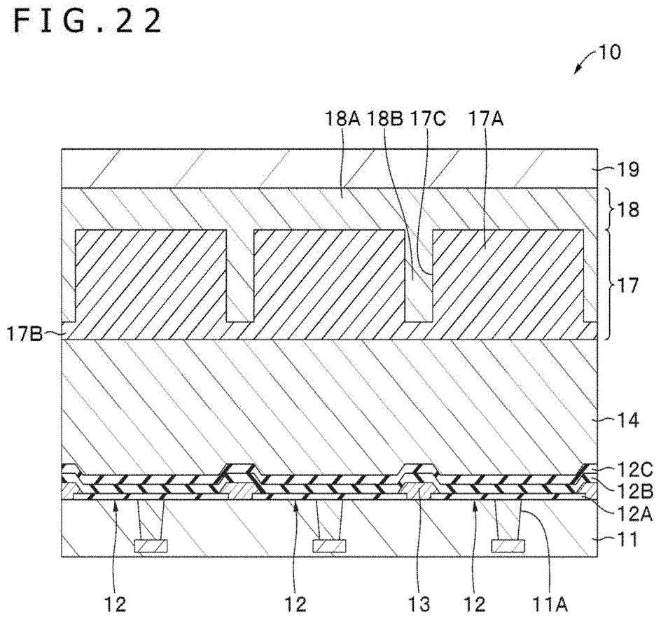

As illustrated in FIG. 22, the display device 10 does not need to include the undercoat layer 15. In this case, the waveguide mode can be extracted by reducing a refractive index difference Δnₐ between the light-emitting elements 12 and the protective layer 14 and a refractive index difference Δn_{b} between the protective layer 14 and the microlens array 17. The refractive index difference Δnₐ and the refractive index difference Δn_{b} are preferably zero or approximately zero.

### Modified Example 14

In the above-described embodiment, the case in which the microlens array is manufactured by using a photosensitive resin in the manufacturing method of the display device 10 has been described, but the manufacturing method of the microlens array is not limited thereto, and the microlens array may be manufactured by using a thin film forming technique, a photolithography technique, and an etching technique as will be described below.

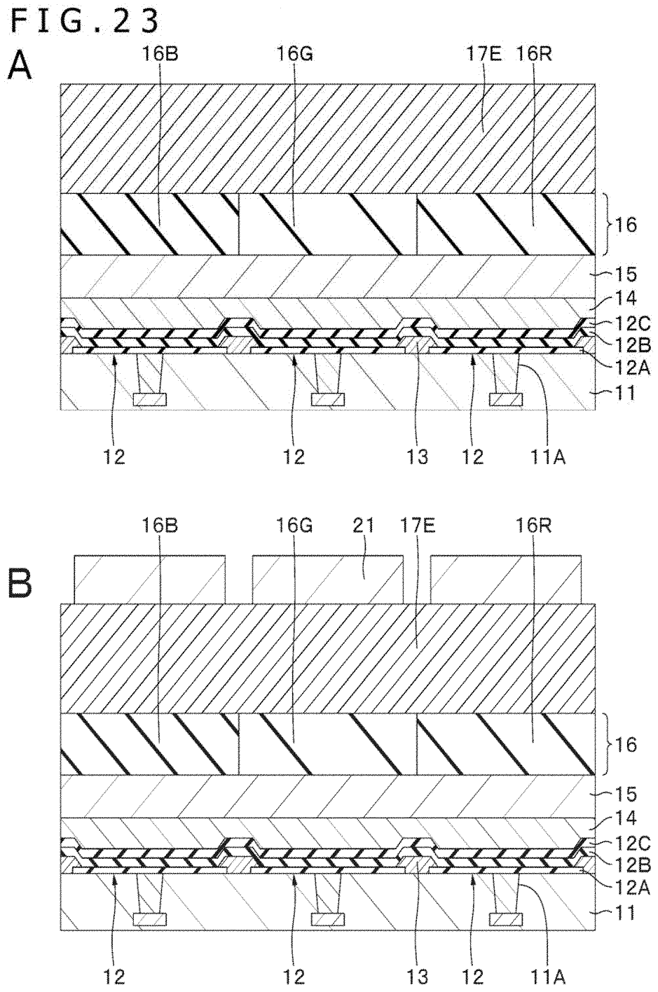

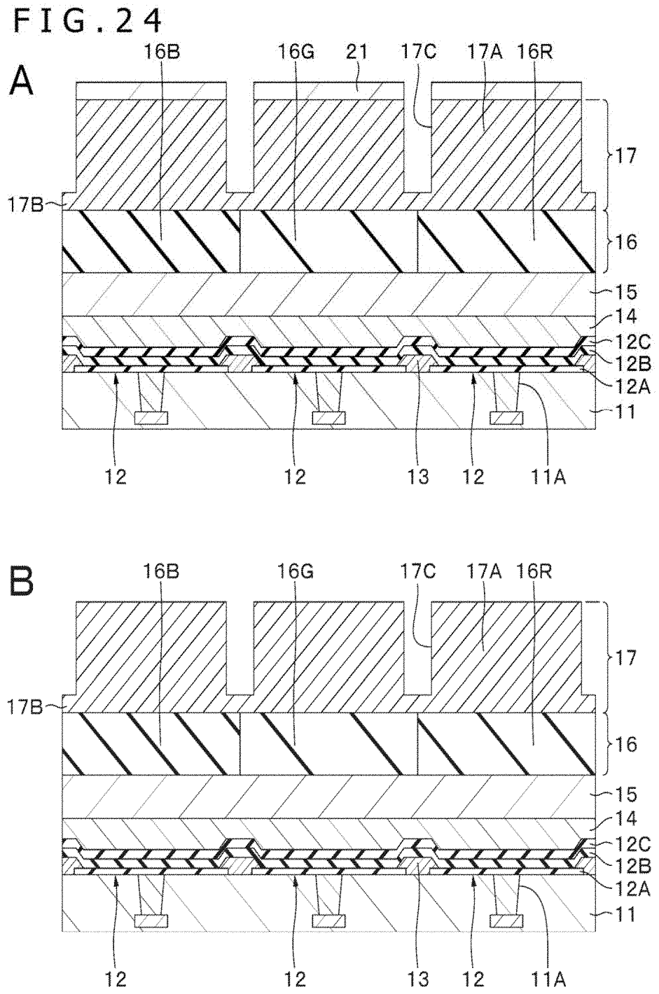

First, as illustrated in FIG. 23A, an inorganic material layer 17E is formed on the color filter 16 by, for example, a vapor deposition method or a CVD method. Next, as illustrated in FIG. 23B, a resist layer 21 is formed on the inorganic material layer 17E by a photolithography technique, and the resist layer 21 is patterned into a prescribed shape. Next, as illustrated in FIG. 24A, the gap 17C is formed in the inorganic material layer 17E by an etching technique to form the microlens array 17. Finally, as illustrated in FIG. 24B, the resist layer 21 is removed. By performing the etching while leaving the resist layer 21 as described above, processing can be performed such that the angle of each side surface of the top portions of each microlenses 17A becomes approximately 90°.

It should be noted that the above-described etching process may be performed until the resist layer 21 is removed. In this case, the above-described step of removing the resist layer 21 can be omitted. It should be noted that the case in which the microlens array 17 is formed by using the inorganic material layer 17E has been described in the above example, but a polymer resin layer may be used instead of the inorganic material layer 17E.

### 5 APPLICATION EXAMPLE

### (Electronic Apparatus)

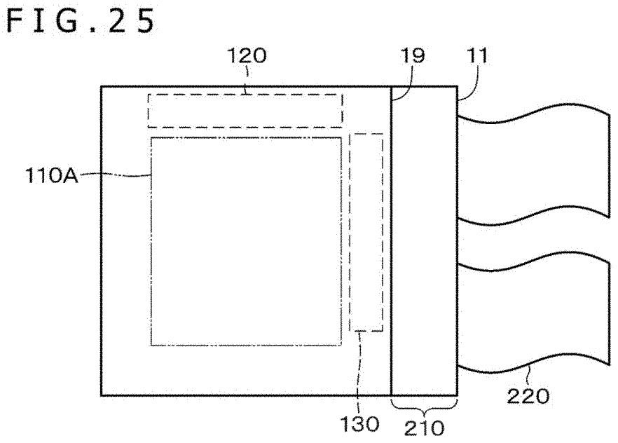

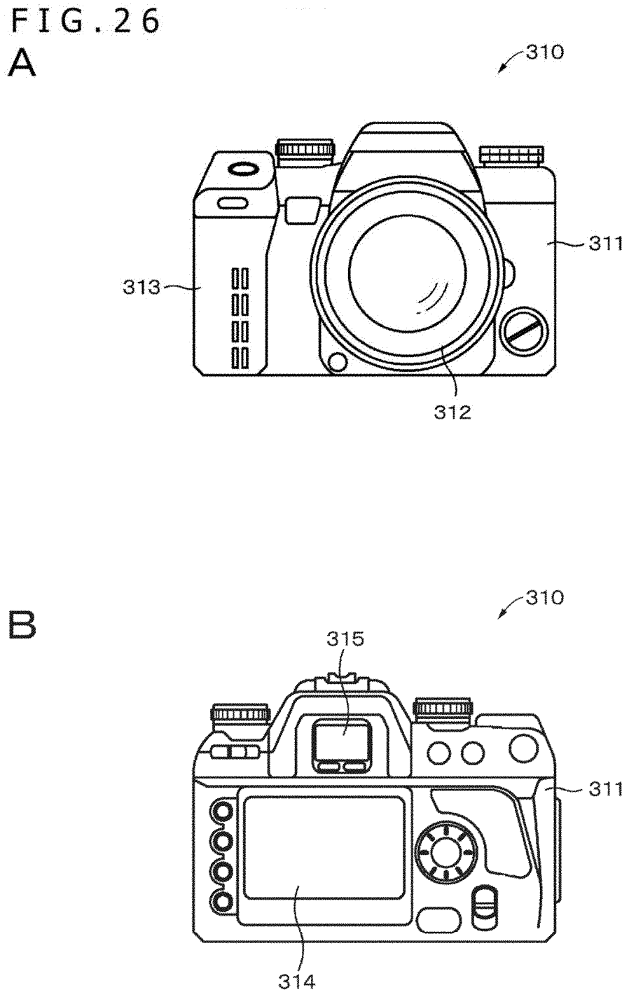

The display device 10 according to any one of the above-described embodiment and modified examples thereof is incorporated into various electronic apparatuses as a module as illustrated in, for example, FIG. 25. In particular, the display device 10 is suitable for an electronic apparatus, such as an electronic viewfinder or a head-mount type display for a video camera or a single-lens reflex camera, for which a high resolution is required and which is used by enlarging near the eyes. This module has a region 210, on one short side of the substrate 11, exposed without being covered with the counter substrate 19 and the resin filled layer 18, and an external connection terminal (not illustrated) is formed in the region 210 by extending wirings of the signal line driving circuit 120 and the scanning line driving circuit 130. A flexible printed circuit (FPC) 220 for inputting and outputting signals may be connected to the external connection terminal.

### Concrete Example 1

FIG. 26A and FIG. 26B illustrate an example of an appearance of a digital still camera 310. The digital still camera 310 is of a lens interchangeable single-lens reflex type, has an interchangeable photographic lens unit (interchangeable lens) 312 substantially in the center of the front of a camera body portion (camera body) 311, and has a grip portion 313 to be held by a photographer on the left side of the front.

A monitor 314 is provided at a position deviated to the left side from the center of the back surface of the camera body portion 311. An electronic viewfinder (eyepiece window) 315 is provided above the monitor 314. The photographer can visually recognize the optical image of a subject guided from the photographic lens unit 312 by looking into the electronic viewfinder 315, to determine the composition. As the electronic viewfinder 315, the display device 10 according to the above-described embodiment or any one of the modified examples thereof can be used.

### Concrete Example 2

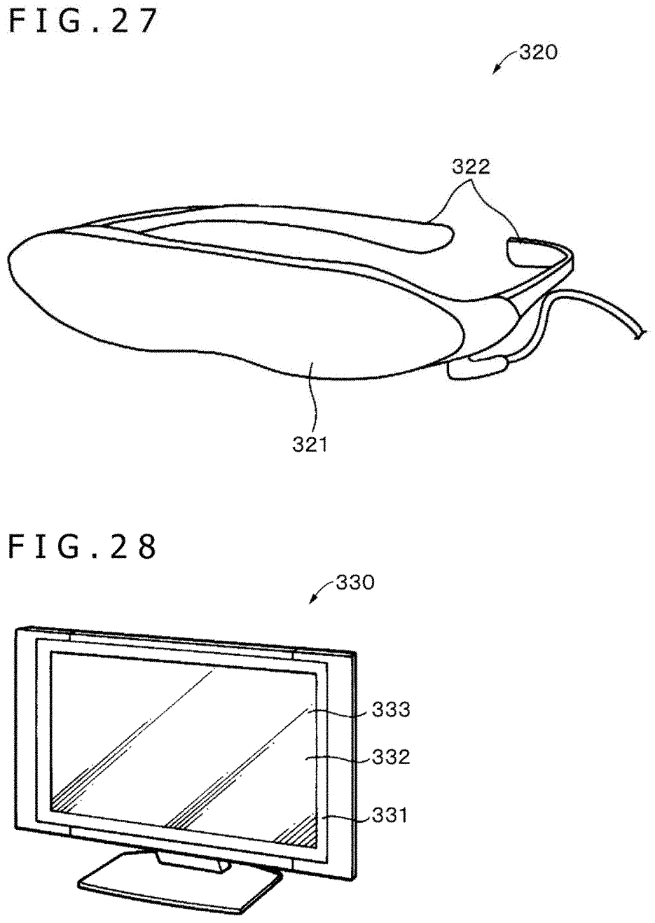

FIG. 27 illustrates an example of an appearance of a head-mounted display 320. The head-mounted display 320 has, for example, ear hooking portions 322 to be worn at the head of a user on both sides of a display portion 321 in a spectacle shape. As the display portion 321, the display device 10 according to the above-described embodiment or any one of the modified examples thereof can be used.

### Concrete Example 3

FIG. 28 illustrates an example of an appearance of a television device 330. The television device 330 has, for example, a video display screen portion 331 including a front panel 332 and a filter glass 333, and the video display screen portion 331 is configured using the display device 10 according to the above-described embodiment or any one of the modified examples thereof.

### (Lighting Device)

In the above-described embodiment, the example in which the present disclosure is applied to the display device has been described, but the present disclosure is not limited thereto, and the present disclosure may be applied to a lighting device.

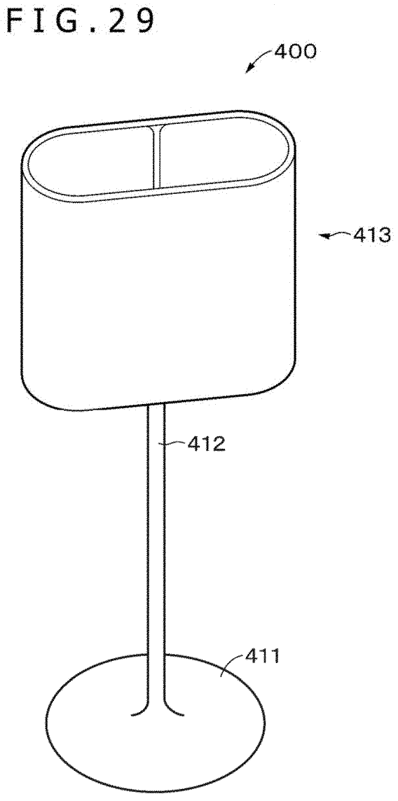

FIG. 29 illustrates an example of an appearance of a stand type lighting device 400. In the lighting device 400, a lighting portion 413 is attached to a support 412 provided on a base 411. As the lighting portion 413, one including a driving circuit for a lighting device instead of the driving circuits for a display device such as the signal line driving circuit 120 and the scanning line driving circuit 130 is used in the display device 10 according to any one of the above-described embodiment and modified examples thereof. In addition, it is not necessary to provide the color filter 16, and the size of an opening of the insulating layer 13 may be appropriately selected according to the optical characteristics of the lighting device 400. Further, an optional shape such as a cylindrical shape or a curved shape illustrated in FIG. 29 can be realized by employing a flexible configuration using films as the substrate 11 and the counter substrate 19. It should be noted that the number of light-emitting elements 12 may be one. In addition, a monochromatic filter may be provided instead of the color filter 16.

Here, the case in which the lighting device is the stand type lighting device 400 has been described, but the form of the lighting device is not limited thereto, and may be, for example, a form installed on a ceiling, a wall, a floor, or the like.

### Test Example

The present disclosure will be specifically described below using test examples, but the present disclosure is not limited to only these test examples.

In the test examples, an FDTD method (Finite-difference time-domain method) was used as a method of a wave analysis simulation. As analysis models for the wave analysis simulation, the following analysis models A to E were used.

### (Analysis Model A)

FIG. 30 illustrates a configuration of an analysis model A. In the analysis model A, microlenses having a cylindrical shape were used.

### (Analysis Model B)

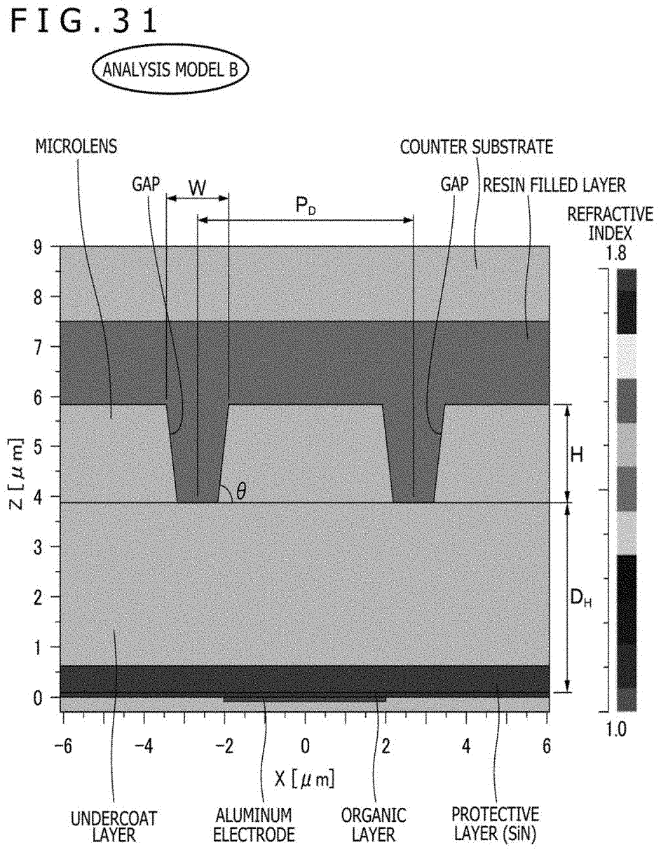

FIG. 31 illustrates a configuration of an analysis model B. In the analysis model B, microlenses having a truncated cone shape were used.

### (Analysis Model C)

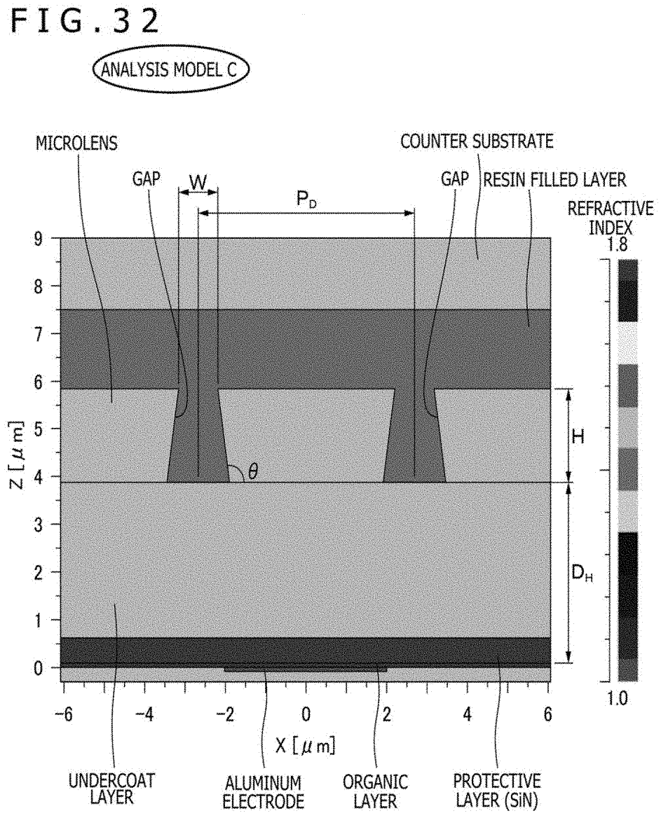

FIG. 32 illustrates a configuration of an analysis model C. In the analysis model C, microlenses having an inverted truncated cone shape were used.

### (Analysis Model D)

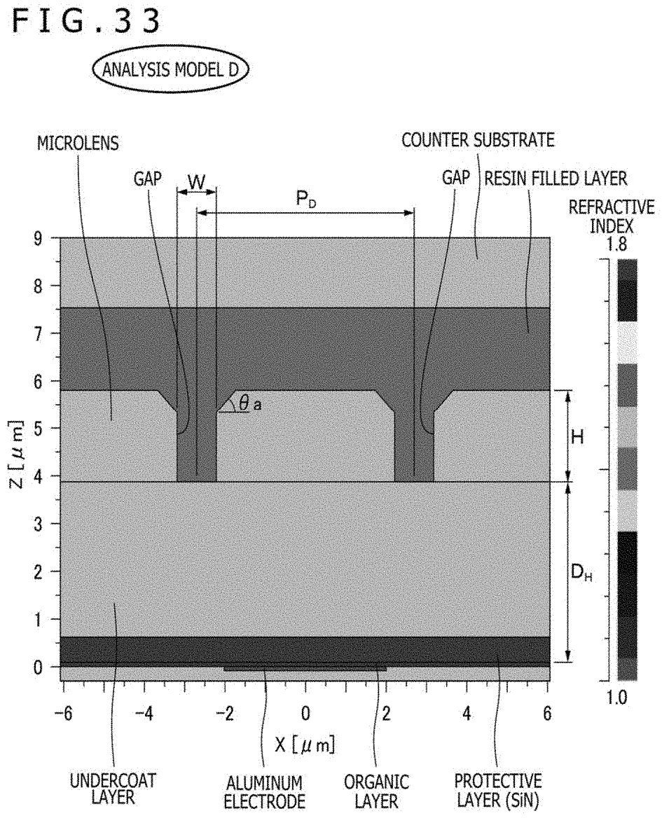

FIG. 33 illustrates a configuration of an analysis model D. In the analysis model D, microlenses whose cylindrical top portions were formed in a cone shape were used.

It should be noted that the refractive index of each layer was set as follows in the above-described analysis models A to D.

Refractive index of the aluminum electrode: 0.96

Refractive index of the organic layer: 1.8

Refractive index of the protective layer: 1.8

Undercoat layer: 1.5

Refractive index of the microlenses: 1.5

Refractive index of the resin filled layer: 1.38

Refractive index of the counter substrate: 1.5

### (Analysis Model E)

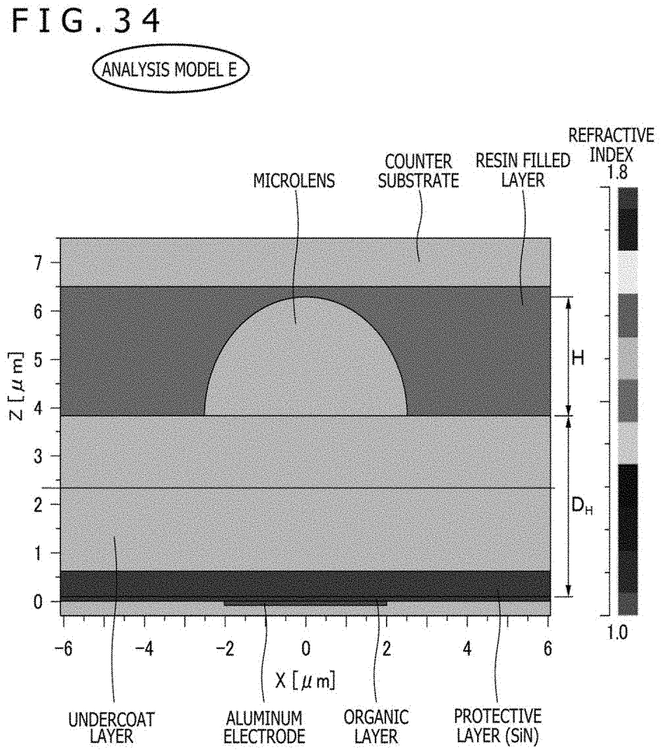

FIG. 34 illustrates a configuration of an analysis model E. In the analysis model E, hemispherical microlenses were used.

The test examples will be described in the following order.

i Study of a relationship between the distance D_{H} between the organic layer and the microlenses and the luminance in the front direction
ii Study of a relationship between the height H of each microlens and the luminance in the front direction
iii Study of a relationship between the width W of the gap between the microlenses and the luminance in the front direction
iv Study of a relationship between the inclined angle θ of each microlens and the luminance in the front direction
v Study of a relationship between the inclined angle θₐ of the top portion of each microlens and the luminance in the front direction

### <i Study of a Relationship Between the Distance D_{E} Between the Organic Layer and the Microlenses and the Luminance in the Front Direction>

### Test Examples 1-1 to 1-4

The luminance in the front direction of the analysis model A when the distance D_{H} between the organic layer and the microlenses was changed was obtained using the analysis model A.

Details of the conditions of the analysis model A are illustrated below.

The shape of each microlens: cylindrical shape

The inclined angle θ of each side surface of the microlenses: 90.0 degrees

The height H of each microlens: 2.0 μm

The distance D_{H} between the organic layer and the microlenses: 1.3 μm (test example 1-1), 2.8 μm (test example 1-2), 3.8 μm (test example 1-3), and 4.9 μm (test example 1-4)

The width W of the gap between the microlenses: 1.0 μm

The pitch P_{D} of the gaps: 5.4 μm

### Test Examples 1-5 to 1-8

The luminance in the front direction of the analysis model E when the distance D_{H} between the organic layer and the microlenses was changed was obtained using the analysis model E.

Details of the setting conditions of the analysis model E are illustrated below.

The shape of each microlens: hemispherical shape

The height H of each microlens: 2.5 μm

The distance D; between the organic layer and the microlenses: 3.8 μm (test example 1-5), 5.3 μm (test example 1-6), 7.3 μm (test example 1-7), and 9.3 μm (test example 1-8)

FIG. 35 illustrates the analysis results of the test examples 1-1 to 1-8. The following can be found from the results.

In the test examples 1-1 to 1-4 using the cylindrical microlenses, the dependency of the luminance in the front direction on the distance D_{H} between the organic layer and the microlenses can be reduced as compared to the test examples 1-5 to 1-8 using the hemispherical lenses as the microlenses. Therefore, in the test examples 1-1 to 1-4 using the cylindrical microlenses, even in a case where the distance D_{H} between the organic layer and the microlenses is small, the effect of improving the luminance in the front direction is large as compared to the test examples 1-5 to 1-8 using the hemispherical lenses as the microlenses.

From the viewpoint of improving the luminance in the front direction, the distance Dr between the organic layer and the microlenses is preferably more than 0.35 μm, more preferably 1.3 μm or more, still more preferably 2.8 μm or more, and particularly, preferably 3.8 μm or more.

When considering in geometrical optics, in a case where a light ray enters the vertical side surfaces of the microlenses, the incident angle and the reflection angle become equal to each other, and thus the extraction in the front direction is not improved. However, when considering in the wave analysis (FDTD), the extraction in the vicinity of the outer periphery of the light source is improved, and the extraction of light in the front direction is improved.

### <ii Study of a Relationship Between the Height H of Each Microlens and the Luminance in the Front Direction>

### Test Examples 2-1 to 2-4

The luminance in the front direction of the analysis model A when the height H of each microlens was changed was obtained using the analysis model A.

Details of the setting conditions of the analysis model A are described below.

The shape of each microlens: cylindrical shape

The inclined angle θ of each microlens: 90.0 degrees

The height H of each microlens: 1.5 μm (test example 2-1), 2.0 μm (test example 2-2), 2.5 μm (test example 2-3), and 3.0 μm (test example 2-4)

The distance D_{H} between the organic layer and the microlenses: 3.8 μm

The width W of the gap between the microlenses: 0.8 μm

The pitch P_{D} between the gaps: 5.4 μm

### Test Examples 2-5 to 2-7

The luminance in the front direction of the analysis model A was obtained similarly to the test examples 2-1 to 2-3 except that the width W of the gap between the microlenses was set to 1.0 μm.

### Test Examples 2-8 to 2-10

The luminance in the front direction of the analysis model A was obtained similarly to the test examples 2-1 to 2-3 except that the width W of the gap between the microlenses was set to 1.2 μm.

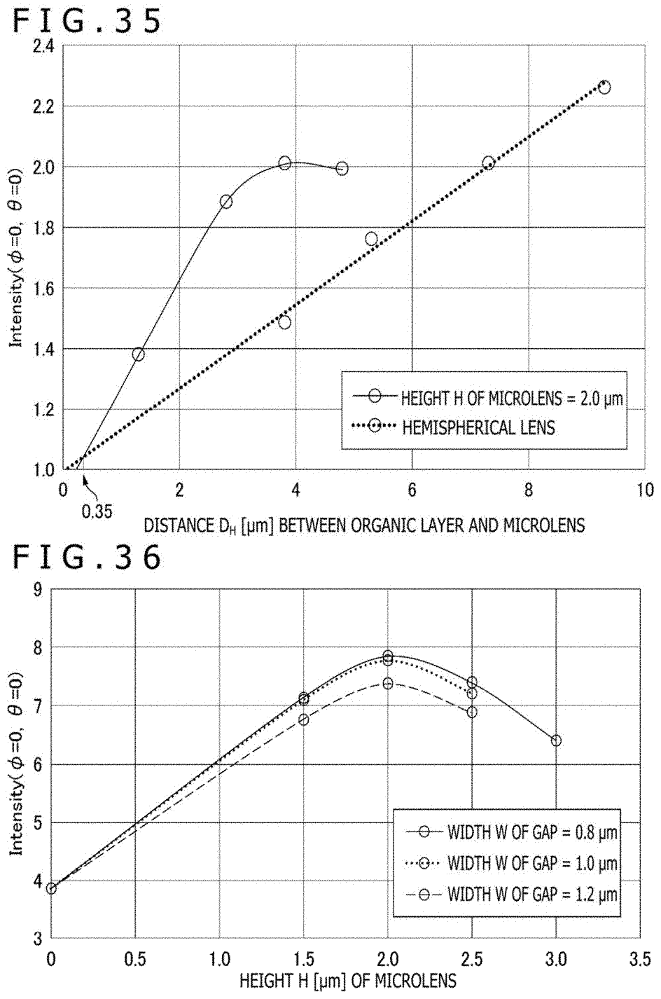

FIG. 36 illustrates the analysis results of the test examples 2-1 to 2-10. The following can be found from the results.

Since the microlenses do not function as simple waveguides, the luminance in the front direction is maximized when the height of each microlens is 2.0 μm.

From the viewpoint of improving the luminance in the front direction, the height H of each microlens is preferably 1.5 μm or more and 2.5 μm or less.

### <iii Study of a Relationship Between the Width W of the Gap Between the Microlenses and the Luminance in the Front Direction>

### Test Examples 3-1 to 3-5

The luminance in the front direction of the analysis model A when the width W of the gap between the microlenses was changed was obtained using the analysis model A.

Details of the setting conditions of the analysis model A are illustrated below.

The shape of each microlens: cylindrical shape

The inclined angle θ of each microlens: 90.0 degrees

The height H of each microlens: 2.5 μm

The distance D_{H} between the organic layer and the microlenses: 3.8 μm

The width W of the gap between the microlenses: 0.4 μm (test example 3-1), 0.6 μm (test example 3-2), 0.8 μm (test example 3-3), 1.0 μm (test example 3-4), and 1.2 μm (test example 3-5)

The pitch P_{D} between the gaps: 5.4 μm

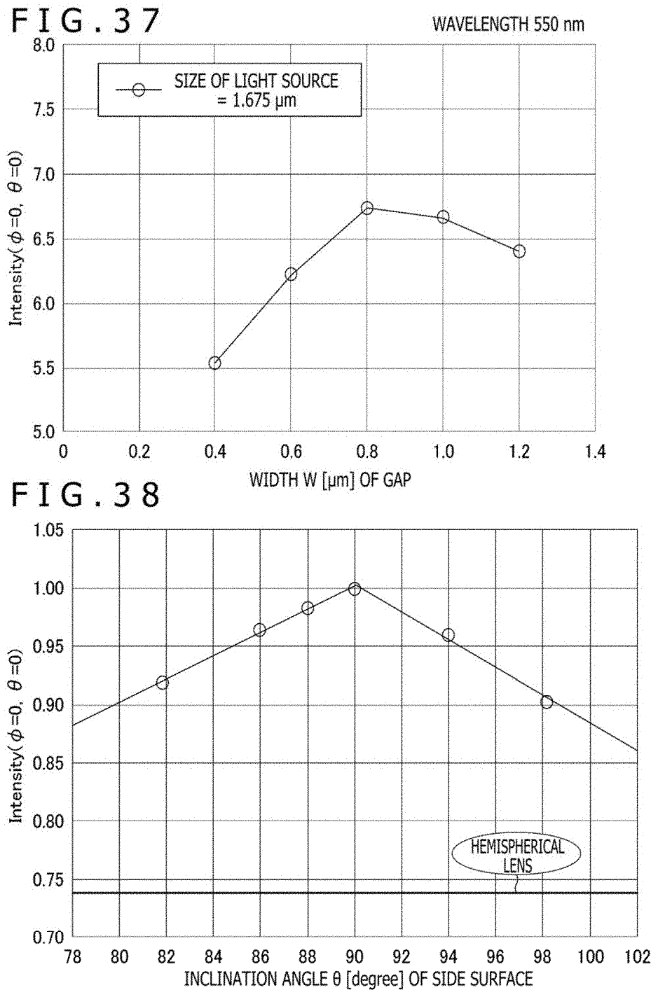

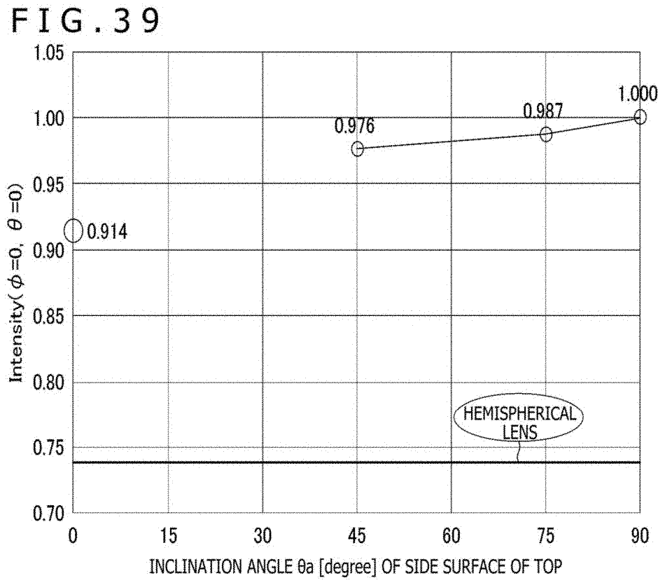

FIG. 37 illustrates the analysis results of the test examples 3-1 to 3-5. The following can be found from the results.

In a case where the width W of the gap between the microlenses is 0.8 μm, the luminance in the front direction is maximized.

From the viewpoint of improving the luminance in the front direction, the width W of the gap between the microlenses is preferably 0.4 μm or more and 1.2μ or less, more preferably 0.6 μm or more and 1.2μ or less, still more preferably 0.8 μm or more and 1.2μ or less, and particularly, preferably 0.8 μm or more and 1.0μ or less.

### <iv Study of a Relationship Between the Inclined Angle θ of Each Microlens and the Luminance in the Front Direction>

### Test Examples 4-1 to 4-6

The luminance in the front direction of each of the analysis models A, B, and C when the inclined angle θ of each lens was changed was obtained using the analysis models A, B, and C.

Details of the conditions of the analysis models A, B, and C are illustrated below.

The shape of each microlens: cylindrical shape (analysis model A), truncated cone shape (analysis model B), and inverted truncated cone shape (analysis model C)

The inclined angle θ of each microlens: 81.8 degrees (test example 4-1), 86.0 degrees (test example 4-2), 88.0 degrees (test example 4-3), 90.0 degrees (test example 4-4), 94.0 degrees (test example 4-5), and 98.2 degrees (test example 4-6)

The height H of each microlens: 2.0 μm

The distance D_{H} between the organic layer and the microlenses: 3.8 μm

The width W of the gap between the microlenses: 1.0 μm

The pitch P_{D} between the gaps: 5.4 μm

FIG. 38 illustrates the analysis results of the test examples 4-1 to 4-6. The following can be found from the results.

In a case where the inclined angle θ of each microlens is 90 degrees, the luminance in the front direction is maximized.

If the inclined angle of each side surface of the microlenses is in the range of 80 to 100 degrees, sufficiently excellent front luminance can be obtained.

From the viewpoint of improving the luminance in the front direction, the inclined angle of each side surface of the microlenses is preferably 81.8 to 98.2 degrees, more preferably 84.0 to 96.0 degrees, still more preferably 86.0 to 94.0 degrees, particularly, preferably 88.0 to 92.0 degrees, and most preferably approximately 90 degrees.

### <v Study of a Relationship Between the Inclined Angle θₐ of the Top Portion of Each Microlens and the Luminance in the Front Direction>

### Test Examples 5-1 to 5-3

The luminance in the front direction of each of the analysis models A and E when the inclined angle θₐ of the top portion of each microlens was changed was obtained using the analysis models A and E.

Details of the conditions of the analysis models A and E are described below.

The shape of each microlens: cylindrical shape (analysis model A) and shape in which the cylindrical top portion was formed in a cone shape (analysis model D)

The height H of each microlens: 2.0 μm

The inclined angle θₐ of the top portion: 45 degrees (test example 5-1), 75 degrees (test example 5-2), and 90 degrees (no inclination at the top portion)

### Test Example 5-3

The distance D_{N} between the organic layer and the microlenses: 3.8 μm

The width W of the gap between the microlenses: 1.0 μm

The pitch P_{D} between the gaps: 5.4 μm

### Test Example 5-4

The luminance in the front direction of the analysis model A was obtained similarly to the test example 5-3 except that the height H of each microlens was set to 1.5 μm. It should be noted that the analysis model A of the test example 5-4 corresponds to the analysis model E used in the test examples 5-1 and 5-2 in which the cone-shaped portion is cut off from the top portion of each microlens.

FIG. 39 illustrates the analysis results of the test examples 5-1 to 5-10. The following can be found from the results.

In a case where each of the entire side surfaces of the microlenses is configured using a vertical plane of 90 degrees, the luminance in the front direction is maximized. However, even if the top portion of each microlens is inclined, the influence on the front luminance is small, and sufficiently excellent front luminance can be obtained.

Although the embodiment and the modified examples thereof of the present disclosure have been specifically described above, the present disclosure is not limited to the above-described embodiment and modified examples thereof, and various modifications based on the technical ideas of the present disclosure can be made.

For example, the configurations, methods, steps, shapes, materials, numerical values, and the like mentioned in the above-described embodiment and modified examples thereof are merely examples, and different configurations, methods, steps, shapes, materials, numerical values, and the like may be used as necessary.

In addition, the configurations, methods, steps, shapes, materials, numerical values, and the like of the above-described embodiment and modified examples thereof may be combined with each other without departing from the gist of the present disclosure.

In addition, in the numerical ranges described stepwise in the above-described embodiment and modified examples thereof, the upper limit value or lower limit value of the numerical range of one stage may be replaced with the upper limit value or lower limit value of the numerical range of another stage.

In addition, the materials exemplified in the above-described embodiment and modified examples thereof can be used alone with one kind or in combination of two or more kinds, unless otherwise specified.

In addition, the present disclosure can also employ the following configurations.

(1)

A display device including:

a substrate having a principal surface;

plural light-emitting elements provided on the principal surface; and

plural structures that are provided on the plural light-emitting elements and that have side surfaces vertical or substantially vertical to the principal surface,

in which a refractive index between the structures is lower than a refractive index of the structures, and

in which a pitch of the light-emitting elements is three times or less a pitch of the structures.

(2)

The display device according to (1), further including:

an upper layer provided on the plural structures,

in which a refractive index of the upper layer is lower than the refractive index of the structures.

(3)

The display device according to (1) or (2),

in which a height of the structures is 1.5 μm or more and 2.5 μm or less.

(4)

The display device according to any one of (1) to (3),

in which a width of a portion between the structures is 0.4 μm or more and 1.2 μm or less.

(5)

The display device according to any one of (1) to (4),

in which the pitch of the light-emitting elements is 1 μm or more and 10 μm or less.

(6)

The display device according to any one of (1) to (5),

in which a distance between the light-emitting elements and the structures is more than 0.35 μm and 7 μm or less.

(7)

The display device according to any one of (1) to (6),

in which an inclined angle θ of the side surfaces with respect to the principal surface of the substrate is 80 degrees or more and 100 degrees or less.

(8)

The display device according to any one of (1) to (7),

in which the structures are provided corresponding to the light-emitting elements, and

in which materials of the structures are the same irrespective of each of the light-emitting elements.

(9)

The display device according to any one of (1) to (8),

in which the plural light-emitting elements include plural kinds of optical elements for emitting light having different wavelengths.

(10)

The display device according to any one of (1) to (8), further including:

a color filter layer provided between the plural light-emitting elements and the plural structures.

(11)

The display device according to any one of (1) to (10),

in which each of the structures has a planar top surface.

(12)

The display device according to any one of (1) to (11),

in which each of the structures has a columnar shape or a substantially columnar shape.

(13)

The display device according to any one of (1) to (12),

in which the plural light-emitting elements include OLEDs.

(14)

The display device according to any one of (1) to (13),

in which the plural light-emitting elements include micro LEDs.

(15)

A display device including:

a substrate having a principal surface;

plural light-emitting elements provided on the principal surface; and

plural structures that are provided on the plural light-emitting elements and that have side surfaces vertical or substantially vertical to the principal surface,

in which a refractive index of a portion between the structures is lower than a refractive index of the structures,

in which a pitch of the light-emitting elements is n times or more (n is an integer equal to or larger than 1) a pitch of the structures.

(16)

An electronic apparatus including:

the display device according to any one of (1) to (15)

### REFERENCE SIGNS LIST

10: Display device
11: Substrate
12: Light-emitting element
12A: First electrode
12B: Organic layer
12B₁: Hole injection layer
12B₂: Hole transport layer
12B₃: Light-emitting layer
12B₄: Electron transport layer
12C: Second electrode
13: Insulating layer
14: Protective layer
15, 20: Undercoat layer
16: Color filter
17: Microlens array
17A: Microlens
17B: Base bottom portion
17C: Gap
17D: Photosensitive resin layer
17E: Inorganic material layer
18: Resin filled layer
18A, 18B: Filled resin
18C: Space
19: Counter substrate
21: Resist Layer
100R, 100G, 100B: Subpixel
110A: Display region
110B: Peripheral region
120: Signal line driving circuit
130: Scanning line driving circuit
120A: Signal line
130A: Scanning line
310: Digital still camera (electronic apparatus)
320: Head-mounted display (electronic apparatus)
330: Television device (electronic apparatus)
400: Lighting device

1. A display device comprising:
a substrate having a principal surface;
plural light-emitting elements provided on the principal surface; and
plural structures that are provided on the plural light-emitting elements and that have side surfaces vertical or substantially vertical to the principal surface,
wherein a refractive index between the structures is lower than a refractive index of the structures, and
wherein a pitch of the light-emitting elements is three times or less a pitch of the structures.

2. The display device according to claim 1, further comprising:
an upper layer provided on the plural structures,
wherein a refractive index of the upper layer is lower than the refractive index of the structures.

3. The display device according to claim 1,
wherein a height of the structures is 1.5 μm or more and 2.5 μm or less.

4. The display device according to claim 1,
wherein a width of a portion between the structures is 0.4 μm or more and 1.2 μm or less.

5. The display device according to claim 1,
wherein the pitch of the light-emitting elements is 1 μm or more and 10 μm or less.

6. The display device according to claim 1,
wherein a distance between the light-emitting elements and the structures is more than 0.35 μm and 7 μm or less.

7. The display device according to claim 1,
wherein an inclined angle θ of the side surfaces with respect to the principal surface of the substrate is 80 degrees or more and 100 degrees or less.

8. The display device according to claim 1,
wherein the structures are provided corresponding to the light-emitting elements, and
wherein materials of the structures are a same irrespective of each of the light-emitting elements.

9. The display device according to claim 1,
wherein the plural light-emitting elements include plural kinds of optical elements for emitting light having different wavelengths.

10. The display device according to claim 1, further comprising:
a color filter layer provided between the plural light-emitting elements and the plural structures.

11. The display device according to claim 1,
wherein each of the structures has a planar top surface.

12. The display device according to claim 1,
wherein each of the structures has a columnar shape or a substantially columnar shape.

13. The display device according to claim 1,
wherein the plural light-emitting elements include OLEDs.

14. The display device according to claim 1,
wherein the plural light-emitting elements include micro LEDs.

15. A display device comprising:
a substrate having a principal surface;
plural light-emitting elements provided on the principal surface; and
plural structures that are provided on the plural light-emitting elements and that have side surfaces vertical or substantially vertical to the principal surface,
wherein a refractive index of a portion between the structures is lower than a refractive index of the structures, and
wherein a pitch of the light-emitting elements is n times or more (n is an integer equal to or larger than 1) a pitch of the structures.

16. An electronic apparatus comprising:
the display device according to claim 1.
